(19) United States
(12) Patent Application Publication
(10) Pub. No.: US 2019/0097059 A1
(43) Pub. Date: Mar. 28, 2019

(54) SEMICONDUCTOR DEVICE

(71) Applicant: Sharp Kabushiki Kaisha, Osaka (JP)

(72) Inventors: Tetsuo KIKUCHI, Sakai City (JP); Tohru DAITOH, Sakai City (JP); Hajime IMAI, Sakai City (JP); Masahiko SUZUKI, Sakai City (JP); Setsuji NISHIMIYA, Sakai City (JP); Teruyuki UEDA, Sakai City (JP); Kengo HARA, Sakai City (JP)

(21) Appl. No.: 16/143,528

(22) Filed: Sep. 27, 2018

(30) Foreign Application Priority Data
Sep. 28, 2017 (JP) 2017-188268

(51) Int. Cl. H01L 29/786; H01L 27/12; H01L 29/24; H01L 29/267; G02F 1/1368

(52) U.S. Cl. CPC H01L 29/7869; H01L 27/1225; H01L 29/24; H01L 29/78633; G02F 1/134363; H01L 29/267; G02F 1/1368; G02F 2001/13685; H01L 29/78696

(57) ABSTRACT

In a semiconductor device, at least one thin-film transistor includes a semiconductor layer, a gate electrode, a gate insulating layer, a source electrode, and a drain electrode. The semiconductor layer has a multilayer structure that includes a plurality of channel formation layers including a first channel formation layer and a second channel formation layer, and at least one middle layer including a first middle layer provided between the first channel formation layer and the second channel formation layer. The first channel formation layer is disposed closer to the gate insulating layer than is the second channel formation layer, and is in contact with the gate insulating layer. The plurality of channel formation layers and the at least one middle layer are all an oxide semiconductor layer. The plurality of channel formation layers each have a mobility higher than that of the at least one middle layer.

### BACKGROUND

### 1. Technical Field

The present invention relates to oxide semiconductor devices.

### 2. Description of the Related Art

Active matrix substrates for use in liquid crystal display devices, etc., include a switching element such as a thin-film transistor (hereinafter referred to as a “TFT”) for each pixel. As such a TFT (hereinafter referred to as a “pixel TFT”), a TFT having an amorphous silicon film as an active layer (hereinafter referred to as an “amorphous silicon TFT”) and a TFT having a polycrystalline silicon film as an active layer (hereinafter referred to as a “polycrystalline silicon TFT”) have conventionally been widely used.

Meanwhile, monolithic integration of a peripheral circuit such as a drive circuit on a substrate is a known technique. Monolithic formation of a drive circuit allows narrowing of a non-display region, and simplification of a mounting process, which lead to a reduction in cost. As used herein, a TFT included in a peripheral circuit monolithically formed on an active matrix substrate is referred to as a “circuit TFT.”

Oxide semiconductors have in recent years been used as a material for the active layers of some TFTs instead of amorphous silicon and polycrystalline silicon. Such TFTs are referred to as “oxide semiconductor TFTs.” Oxide semiconductors have a higher mobility than that of amorphous silicon. Therefore, oxide semiconductor TFTs can operate at higher speed than that of amorphous silicon TFTs. Therefore, oxide semiconductor TFTs may preferably be used as a circuit TFT as well as a pixel TFT.

It has been proposed that in an oxide semiconductor TFT, a multilayer semiconductor layer in which a plurality of oxide semiconductor layers are stacked should be used as an active layer. As used herein, such a TFT structure is referred to as a “multilayer channel structure,” and a TFT having a multilayer channel structure is referred to as a “multilayer channel structure TFT.” For example, Japanese Laid-Open Patent Publication No. 2013-41945 describes TFT that includes, as an active layer, a multilayer semiconductor layer including two oxide semiconductor layers (such a TFT is referred to as a “two-layer channel structure TFT”).

Japanese Laid-Open. Patent Publication No. 2014-033194 describes a bottom-gate structure TFT that has an active layer having a three-layer structure in which a first oxide semiconductor layer, a second oxide semiconductor layer, and a third oxide semiconductor layer are stacked on a gate insulating film in that order (such a TFT is referred to as a “three-layer channel structure TFT”). In the three-layer channel structure TFT described in Japanese Laid-Open Patent Publication No. 2014-033194, the second oxide semiconductor layer has a smaller energy gap than those of the first and third oxide semiconductor layers, and functions as a channel. According to Japanese Laid-Open Patent Publication No. 2014-033194, the first oxide semiconductor layer is provided in order to separate the channel from the gate insulating film, and form a buried channel structure. The third oxide semiconductor layer is provided as a buffer layer for preventing or reducing diffusion elements contained the source and drain electrodes into the channel.

### SUMMARY

Oxide semiconductors have a mobility that is about an order of magnitude smaller than that of polycrystalline silicon, and therefore, oxide semiconductor TFTs have smaller current drive power than that of polycrystalline silicon TFTs. Therefore, there is a demand for an oxide semiconductor TFT having higher current drive power.

If the current drive power of an oxide semiconductor TFT is increased, and such an oxide semiconductor TFT is used as a pixel TFT, the size or definition of an active matrix substrate can be increased. In addition, higher-frequency drive (e.g., 120 Hz) can be achieved. Furthermore, if such a TFT is used as a circuit TFT, the size of the circuit TFT can be reduced, and therefore, the area of the peripheral circuit can be reduced. Therefore, the power consumption or frame of an active matrix substrate can be reduced.

The present inventors has studied to find that in conventional TFT structures described in Japanese Laid-Open Patent Publication Nos. 2013-41945 and 2014-033194, etc., it may be difficult to control the threshold voltage Vth, and at the same time, increase the current drive power (on-current) of an oxide semiconductor TFT. This will be described below.

With the above circumstances in mind, one non-limiting, and exemplary embodiment provides a technique to a semiconductor device including an oxide semiconductor TFT that can have a high mobility.

In one general aspect, a semiconductor device disclosed herein comprises a substrate, and a plurality of thin-film transistors supported by the substrate. At least one of the plurality of thin-film transistors includes a semiconductor layer, a gate electrode, a gate insulating layer provided between the gate electrode and the semiconductor layer, and a source electrode and a drain electrode electronically connected to the semiconductor layer. The semiconductor layer has a multilayer structure including a plurality of channel formation layers including a first channel formation Layer and a second channel formation layer, and at least one middle layer including a first middle layer provided between the first channel formation layer and the second channel formation layer. The first channel formation layer is disposed closer to the gate insulating layer than is the second channel formation layer, and is in contact with the gate insulating layer. The plurality of channel formation layers and the at least one middle layer are all an oxide semiconductor layer. The plurality of channel formation layers each have a mobility higher than that of the at least one middle layer.

In one non-limiting, and exemplary embodiment, the plurality of channel formation layers and the at least one middle layer all include a first metal element and a second metal element. The first metal element is In, and the second metal element is one of Ga and Zn. The atomic proportion of the first metal element to all metal elements contained in each of the plurality of channel formation layers is different from the atomic proportion of the first metal element to all metal elements contained in the at least one middle layer. In each of the plurality of channel formation layers, the atomic proportion of the first metal element to all the metal elements is greater than or equal to the atomic proportion of the second metal element to all the metal elements. In the at least one middle layer, the atomic proportion the first metal element to all the metal elements is smaller than or equal to the atomic proportion of the second metal element to all the metal elements.

In another general aspect, a semiconductor device disclosed herein comprises a substrate, and a plurality of thin-film transistors supported by the substrate. At least one of the plurality of thin-film transistors includes a semiconductor layer, a gate electrode, a gate insulating layer provided between the gate electrode and the semiconductor layer, and a source electrode and a drain electrode electronically connected to the semiconductor layer. The semiconductor layer has a multilayer structure including a plurality of channel formation layers including a first channel formation layer and a second channel formation layer, and at least one middle layer including a first middle layer provided between the first channel formation layer and the second channel formation layer. The first channel formation layer is disposed closer to the gate insulating layer than is the second channel formation layer, and is in contact with the gate insulating layer. The plurality of channel formation layers and the at least one middle layer are all an oxide semiconductor layer including a first metal element and a second metal element The first metal element is In, and the second metal element is one of Ga and Zn. The atomic proportion of the first metal element to all metal elements contained in in each of the plurality of channel formation layers is different from the atomic proportion of the first metal element to all metal elements contained in the at least one middle layer. In each of the plurality of channel formation layers, the atomic proportion of the first metal element to all the metal elements is greater than or equal to the atomic proportion of the second metal element to all the metal elements. In the at least one middle layer, the atomic proportion of the first metal element to all the metal elements is smaller than or equal to the atomic proportion of the second metal element to all the metal elements.

In one non-limiting, and exemplary embodiment, the first channel formation layer and the second channel formation layer have substantially the same composition.

In one non-limiting, and exemplary embodiment, the first middle layer is in contact with the first channel formation layer and the second channel formation layer.

In one non-limiting, and exemplary embodiment, the first channel formation and the second channel formation layer each have a thickness smaller than a thickness of the first middle layer.

In one non-limiting, and exemplary embodiment, the plurality of channel formation layers further include a third channel formation layer provided on an opposite side of the second channel formation layer from the first middle layer. The at least one middle layer further includes a second middle layer provided between the third channel formation layer and the second channel formation layer.

In one non-limiting, and exemplary embodiment, the gate electrode is disposed between the semiconductor layer and the substrate.

In one non-limiting, and exemplary embodiment, the at least one thin-film transistor has a channel etch structure. The multilayer structure of the semiconductor layer includes a protective layer as an uppermost layer. The protective layer is an oxide semiconductor layer having a mobility lower than those of the plurality of channel formation layers.

In one non-limiting, and exemplary embodiment, the at least one thin-film transistor has an etch-stop structure.

In one non-limiting, and exemplary embodiment, the at least one thin-film transistor further includes an upper electrode provided on the semiconductor layer with an upper insulating layer interposed therebetween.

In one non-limiting, and exemplary embodiment, one of the plurality of channel formation layers is an uppermost layer of the multilayer structure, and is in contact with the upper insulating layer.

In one non-limiting, and exemplary embodiment, the gate electrode is disposed on an opposite side of the semiconductor layer from the substrate with the gate insulating layer interposed between the gate electrode and the semiconductor layer.

In one non-limiting, and exemplary embodiment, the gate Insulating layer is disposed on a portion of the semiconductor layer, and is located only between the semiconductor layer and the gate electrode. The at least one thin-film transistor further includes an interlayer insulating layer covering the semiconductor layer, the gate electrode, and the gate insulating layer. The source electrode and the drain electrode are each disposed on the interlayer insulating layer, and are each in contact with the semiconductor layer in an opening provided in the interlayer insulating layer.

In one non-limiting, and exemplary embodiment, the at least one thin-film transistor further includes a lower electrode provided between the substrate and the semiconductor layer, and a lower insulating layer provided between the lower electrode and the semiconductor layer.

In one non-limiting, and exemplary embodiment, one of the plurality of channel formation layers is a lowermost layer of the multilayer structure, and is in contact with the lower insulating layer.

In one non-limiting, and exemplary embodiment, the semiconductor device is an active matrix substrate having a display region including a plurality of pixels, and a non-display region other than the display region.

In one non-limiting, and exemplary embodiment, the at least one thin-film transistor includes a pixel TFT provided at each of the plurality of pixels.

In one non-limiting, and exemplary embodiment, the semiconductor device further comprises a drive circuit provided in the non-display region. The at least one thin-film transistor includes a circuit TFT included in the drive circuit.

In one non-limiting, and exemplary embodiment, the plurality of channel formation layers and the at least one middle layer all contain In, Ga, and Zn.

In one non-limiting, and exemplary embodiment, the plurality of channel formation layers and the at least one middle layer are all a crystalline oxide semiconductor layer.

According to the above aspects, a semiconductor device including an oxide semiconductor TFT that can have a high mobility can be provided.

### BRIEF DESCRIPTION OF THE DRAWINGS

FIG. 1A is a schematic cross-sectional view of a TFT 101 in a semiconductor device according to a first embodiment. FIG. 1B is an enlarged cross-sectional view of a semiconductor layer 7 of the TFT 101.

FIGS. 2A-2C are schematic cross-sectional views of semiconductor layers 91, 92, and 93 in TFTs of comparative examples 1-3, respectively.

FIG. 3 is a diagram illustrating VG (gate-source voltage)-ID (drain current) characteristics of each of TFTs of an example and the comparative examples.

FIG. 4 is an enlarged cross-sectional view showing a variation of the semiconductor layer 7.

FIGS. 5A and 5B are enlarged cross-sectional views showing other variations of the semiconductor layer 7.

FIG. 6 is a schematic cross-sectional view. illustrating another TFT 102 according to the first embodiment.

FIG. 7 is a schematic diagram showing an example semiconductor device (active matrix substrate) 1000 according to the first embodiment.

FIGS. 8A and 8B are a plan view of one pixel region P in the active matrix substrate 1000, and a cross-sectional view thereof taken along line I-I′, respectively.

FIG. 9 is a diagram illustrating a shift register circuit included in a gate driver (monolithic gate driver) GD.

FIG. 10A is a diagram showing an example unit circuit SRk. FIG. 10B is a diagram showing a signal waveform in the unit circuit SRk.

FIG. 11A is a cross-sectional view of a TFT 103 according to a second embodiment. FIG. 11B is an enlarged cross-sectional view of a semiconductor layer 7 included in the TFT 103.

FIG. 12A is a plan view illustrating a TFT 104 (output transistor T5) according to the second embodiment. FIG. 12B is a cross-sectional view of the TFT 104 taken along line II-II′ of FIG. 12A.

FIG. 13A is a cross-sectional view of a TFT 105 according to a third embodiment. FIG. 13B is an enlarged cross-sectional view of a semiconductor layer 27 of the TFT 105.

FIG. 14 is a cross-sectional view illustrating another TFT 106 according to the third embodiment.

### DETAILED DESCRIPTION

### First Embodiment

A semiconductor device according to a first embodiment will now be described with reference to the accompanying drawings. The semiconductor device of this embodiment includes an oxide semiconductor TFT. Examples of the semiconductor device of this embodiment include a wide variety of devices, such as a circuit substrate (e.g., an active matrix substrate), various display devices, and electronic apparatuses.

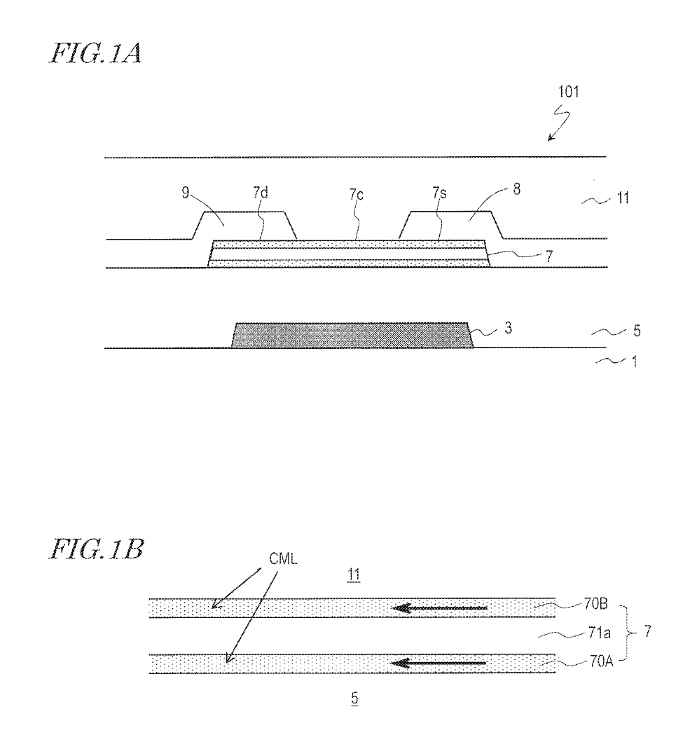

FIG. 1A is a schematic cross-sectional view showing an example oxide semiconductor TFT 101 in the semiconductor device of this embodiment. FIG. 1B is an enlarged cross-sectional view of a semiconductor layer 7 of the TFT 101.

The semiconductor device of this embodiment includes a substrate 1 and an oxide semiconductor TFT (hereinafter simply referred to as a “TFT”) 101. The TFT 101 may be covered by an upper insulating layer 11.

The TFT 101 includes a gate electrode 3 supported on the substrate 1, a semiconductor layer 7, a gate insulating layer 5 provided between the semiconductor layer 7 and the gate electrode 3, and a source electrode 8 and a drain electrode 9 electronically connected to the semiconductor layer 7.

In this example, the TFT 101 is a channel-etch bottom-gate structure TFT. The gate electrode 3 is disposed on a side closer to the substrate 1 of the semiconductor layer 7. The gate insulating layer 5 covers the gate electrode 3. The semiconductor layer 7 is disposed on the gate insulating layer 5 directly above the gate electrode 3 with the gate insulating layer 5 interposed between the semiconductor 7 and the gate electrode 3. The source electrode 8 and the drain electrode 9 are each disposed in contact with a portion of the upper surface of the semiconductor layer 7. The portion of the semiconductor layer 7 that is in contact with the source electrode 8 is referred to as a “source contact region 7s”. The portion of the semiconductor layer 7 that is in contact with the drain electrode 9 is referred to as a “drain contact region 7d”. As viewed in the direction of the normal to the substrate 1, a region that is located between the source contact region 7s and the drain contact region 7d and overlays the gate electrode 3 is a “channel region 7c.”

In this embodiment, the semiconductor layer 7 has a multilayer structure. The multilayer structure of the semiconductor layer 7 has a plurality of channel formation layers including a first channel formation layer 70A and a second channel formation layer 70B (hereinafter collectively referred to as “channel formation layers 70”), and at least one middle layer including a first middle layer 71a interposed between the first channel formation layer 70A and the second channel formation layer 70B (hereinafter collectively referred to as “middle layers 71”). The first channel formation layer 70A is disposed closer to the gate insulating layer 5 than is the second channel formation layer 70B, and is in contact with the gate insulating layer 5. The channel formation layers 70 and the middle layers 71 are all an oxide semiconductor layer.

The channel formation layers 70 have a higher mobility than those of the middle layers 71 (in other words, the channel formation layers 70 have a lower band gap than those of the middle layers 71). The compositions (composition ratios) of the channel formation layers 70 and the middle layers 71 are controlled such that the channel formation layers 70 can have a higher mobility than those of the middle layers 71.

In this example, the semiconductor layer 7 has a three-layer structure in which the first channel formation layer 70A, the first middle layer 71a, and the second channel formation layer 70B are stacked in that order with the first channel formation layer 70A closest to the gate insulating layer 5. The first channel formation layer 70A is in contact with the gate insulating layer 5. The uppermost layer (in this example, the second channel formation layer 70B) of the semiconductor layer 7 is in contact with the upper insulating layer 11. An opposite surface (here, the upper surface) of the first channel formation layer 70A from the gate insulating layer 5 may be in contact with the first middle layer 71a. A surface of the second channel formation layer 70B closer to the first middle layer 71a may be in contact with the first middle layer 71a.

In this embodiment, the channel formation layers 70 (here, the first and second channel formation layers 70A and 70B) of the semiconductor layer 7 function as a layer CML through which most carriers flow (such a layer is hereinafter referred to as a “carrier movement layer”). In this example, as shown by arrows in FIG. 1B, carriers (electrons) move in the first and second channel formation layers 70A and 70B between the source electrode 8 and the drain electrode 9. In the semiconductor layer 7, a plurality of (here, two) carrier movement layers CML are provided, and therefore, an on-current can be increased compared to the case where a single carrier movement layer CML is provided.

In addition, because the middle layer 71, which has a lower mobility, is provided between the two carrier movement layers CML, the threshold voltage Vth of the TFT 101 can be shifted in the positive direction, i.e., can be made more positive. Therefore, for example, in the case where the TFT 101 is used as a circuit TFT, the off-leakage current of the circuit TFT can be reduced, and therefore, an operation failure due to the off-leakage current can be prevented or reduced.

Thus, in this embodiment, the TFT 101 can have high current drive power, and the drive voltage Vth of the TFT 101 can be controlled to a desired value. The TFT 101 is preferably applicable to, for example, both a pixel TFT and a circuit TFT of an active matrix substrate.

The semiconductor layer 7 has a multilayer structure including at least the channel formation layer 70A, the first middle layer 71a, and the second channel formation layer 70B, i.e., the multilayer structure is not limited to a three-layer structure. The semiconductor layer 7 preferably has a structure in which the channel formation layers 70 and the middle layers 71 are alternately put on top of each other, irrespective of the number of layers. If, in such a structure, the number of channel formation layers 70 in the semiconductor layer 7 is increased, the current drive power can be further improved.

Note that in the conventional two-layer channel structure TFT described in Japanese Laid-Open Patent Publication No. 2013-41945, the two-layer structure semiconductor layer has an oxide semiconductor layer that may have a high mobility (high-mobility layer) and a low-mobility layer that has a low mobility, with the high-mobility layer closer to the gate insulating layer. In this structure, only the high-mobility layer of the two layers functions as a carrier movement layer CML. That is, only one carrier movement layer CML is provided. In contrast to this, in this embodiment, a plurality of carrier movement layers CML can be provided, and therefore, the on-current of the TFT 101 can be further increased.

In the conventional three-layer channel structure TFT described in Japanese Laid-Open Patent Publication No. 2014-033194, the second oxide semiconductor layer (high-mobility layer) having a low energy gap is disposed in the middle of the three-layer structure semiconductor layer, i.e., the high-mobility layer is interposed between the first and third oxide semiconductor layers having a high energy gap (low-mobility layers). The present inventors has studied such a three-layer channel structure TFT to find that in this structure, a portion of carriers flow through the low-mobility layer that is in contact with the gate insulating layer, so that a high on-current may not be achieved. In particular, if the thickness of the low-mobility layer is increased in order to control the threshold voltage Vth, carriers can flow more easily through the low-mobility layer, so that the on-current is likely to further decrease. On the other hand, if the thickness of the low-mobility layer is reduced, the reduction in the on-current can be decreased, and the effect of shifting the threshold voltage Vth of the TFT in the positive direction is likely to be insufficient. Therefore, it is difficult to achieve the control of the threshold voltage Vth and high current drive power simultaneously. In contrast to this, in this embodiment, even in the case where the thicknesses of the middle layers 71 are increased, most carriers flows through the channel formation layers 70, and therefore, a sufficient level of current drive power can be ensured, and at the same time, the threshold voltage Vth can be highly flexibly controlled by the middle layers 71.

### Composition and Thickness of Each Layer of Semiconductor Layer 7

The compositions of the channel formation layers 70 and the middle layers 71 may each be controlled such that the mobilities of the channel formation layers 70 are higher than those of the middle layers 71. Note that even when the channel formation layers 70 have a composition that allows high mobility, the actual mobilities of a portion of the channel formation layers 70 may be reduced due to process damage. For example, in a channel-etch TFT, the uppermost channel formation layer 70 (here, the second channel formation layer 70B) of the semiconductor layer 7 is likely to be damaged in a source-drain separation step.

The channel formation layers 70 and the middle layers 71 may both contain In, Ga, and/or Zn. In is herein referred to as a “first metal element,” and any one of Ga and Zn is herein referred to as a “second metal element.” For example, the following tendency is known, i.e., as the proportion of the first metal element in an oxide semiconductor increases, the mobility increases, and as the proportion of the second metal element in an oxide semiconductor increases, the mobility decreases and the crystallinity increases. Therefore, by adjusting the proportions of these metal elements, an oxide semiconductor layer having a desired mobility can be provided.

The ratio of the number of first metal element atoms to the number of all metal element atoms in each channel formation layer 70 (such a ratio is herein referred to as an “atomic proportion”) may be different from the ratio of the number of first metal element atoms to the number of all metal element atoms in each middle layer 71. As an example, in each channel formation layer 70, the ratio of the number of first metal element atoms to the number of all metal element atoms may be greater than or equal to the ratio of the number of second metal element atoms to the number of all metal element atoms. Preferably, the ratio of the number of first metal element atoms to the number of all metal elements may be greater than the ratio of the number of second metal element atoms to the number of all metal element atoms. Meanwhile, in each middle layer 71, the ratio of the number of first metal element atoms to the number of all metal element atoms may be smaller than or equal to the ratio of the number of second metal element atoms to the number of all metal element atoms. This allows the mobilities of the channel formation layers 70 to be higher than those of the middle layers 71.

The compositions of the channel formation layers 70 and the middle layers 71 are not limited to those described above. In the case where the channel formation layers 70 and the middle layers 71 are formed of the same metal elements (e.g., the channel formation layers 70 and the middle layers 71 are all an In—Ga—Zn—O semiconductor layer), the ratio of the number of In atoms to the number of all metal element atoms in each channel formation layer 70 may be higher than the ratio of the number of In atoms to the number of all metal element atoms in each middle layer 71, irrespective of the ratio of the number of second metal element atoms to the number of all metal element atoms. This allows the mobilities of the channel formation layers 70 to be higher than those of the middle layers 71.

Examples of the oxide semiconductor layer containing the first and second metal elements, which can be used as the channel formation layers 70 and the middle layers 71, include an In—Ga—Zn—O semiconductor layer, an In—Sn—Zn—O semiconductor layer, an In—Al—Sn—Zn—O semiconductor layer, an In—Zn—O semiconductor layer, an In—Ga—O semiconductor layer, an In—Ga—Zn—Sn—O semiconductor layer, and an In—Ga—Sn—O semiconductor layer. Note that the channel formation layers 70 and/or the middle layer 71 may contain only one or none of the first and second metal elements. The channel formation layers 70 and the middle layers 71 may be formed of the same set of metal elements or different sets of metal elements.

The channel formation layers 70 included in the semiconductor layer 7 may have the same or different compositions. The term “different compositions” with respect to layers means that the layers contain different sets of metal elements or different ratios of metal elements. The channel formation layers 70 may have the same or different thicknesses. As an example, the first and second channel formation layers 70A and 70B may have substantially the same composition and thickness (i.e., may be formed under conditions that allow the first and second channel formation layers 70A and 70B to have the same composition and thickness). As a result, a plurality of carrier movement layers CML having the same characteristics can be provided in the semiconductor layer 7 of the 101, whereby characteristics of the TFT can be more easily controlled. Likewise, in the case where the semiconductor layer 7 has a plurality of middle layers 71, the middle layers 71 may have the same or different compositions. The middle layers 71 may have the same or different thicknesses.

Preferable compositions of the channel formation layers 70 and the middle layers 71 will now be described. In the description that follows, the ratio (composition ratio) of the number of In atoms to the number of all metal element atoms contained in an oxide semiconductor is abbreviated to an “In ratio”, and the ratio of the number of Zn atoms to the number of all metal element atoms contained in an oxide semiconductor is abbreviated to a “Zn ratio.” For example, the In ratio of an In—Ga—Zn—O semiconductor layer refers to the proportion of the number of In atoms to the total number of In, Ga, and Zn atoms. In this case, the In ratio is represented by [In]/([In]+[Ga]+[Zn]), where [In] represents the number of In atoms, [Ga] represents the number of Ga atoms, and [Zn] represents the number of Zn atoms.

The In ratio of each channel formation layer 70 may be higher than or equal to the Zn ratio or the Ga ratio ([In]≥[Zn] and/or [In]≥[Ga]). The In ratio of each channel formation layer 70 may, for example, be higher than or equal to 1/3. In the case of the channel formation layers 70 are an In—Ga—Zn—O semiconductor layer, the Ga ratio or the Zn ratio may be lower than or equal to 1/3.

An example preferable composition range in the case where the channel formation layers 70 are an In—Ga—Zn—O semiconductor layer is as follows:

[In]/([In]+[Ga]+[Zn])≥1/3;

[In]≥[Ga], [In]≥[Zn], [Zn]≥[Ga]; and

[Ga]/([In]+[Ga]+[Zn])≥1/3.

The channel formation lavers 70 may be formed of an In—Ga—Zn oxide semiconductor having a composition (atomic ratio) of In:Ga:Zn=1:1:1 (=1/3:1/3:1/3), In:Ga:Zn=3:1:2 (=3/6:1/6:2/6), In: Ga: Zn=4:2:3 (=4/9:2/9:3/9), In:Ga:Zn=5:1:3 (=5/9:1/9:3/9), In:Ga:Zn=5:3:4 (=5/12:3/12:4/12), In:Ga:Zn=6:2:4 (=6/12:2/12:4/12), In:Ga:Zn=7:1:3 (=7/11:1/11:3/11), or In:Ga:Zn=5:1:4 (=5/10:1/10:4/10), or an oxide semiconductor having a similar composition. Note that when a sputtering target having the above composition is used to form an oxide semiconductor layer, an error may occur or the layer may be doped with impurities during a process. Even in such a case, the formed oxide semiconductor layer may have a composition corresponding to (substantially equal to) the composition of the sputtering target.

Meanwhile, the Zn or Ga ratio of each middle layer 71 may be higher than or the In ratio ([In]<[Zn] and/or [In]<[Ga]). The Zn ratio or the Ga ratio may, for example, be higher than or equal to 1/2. In the case where the middle layers 71 are an In—Ga—Zn—O semiconductor layer, the In ratio may be lower than 1/3.

An example preferable composition range in the case where the middle layers 71 are an In—Ga—Zn—0 semiconductor layer is as follows:

[In]/[In]+[Ga]+[Zn])<1/3;

[Zn]>[In]; and

[Ga]>[In].

Alternatively, in the case where the In ratio of each channel formation layer 70 is higher than the Zn ratio or the Ga ratio ([In]>[Zn]and/or [In]>[Ga]), the Zn ratio and/or the Ga ratio of each middle layer 71 may be higher than the In ratio or may be the same as the In ratio ([In]=[Zn]and/or [In]=[Ga]).

The middle layers 71 may be formed of an In—Ga—Zn—O oxide semiconductor having a composition (atomic ratio) of In:Ga:Zn32 1:3:2 (=1/6:3/6:2/6), In:Ga:Zn=2:4:3 (=2/94/9:3/9), In:Ga:Zn=(=1/9:5/9:3/9), In:Ga:Zn=1:3:6 (=1/10:3/10:6/10), or In:Ga:Zn=1:1:1 (=1/3:1/3:1/3), or an oxide semiconductor having a similar composition.

The thicknesses of the channel formation layers 70 are not particularly limited, and may, for example, be greater than or equal to 5 nm. The thickness of 5 nm or more can more effectively increase the on-current. On the other hand, if the channel formation layers 70 are excessively thick, the threshold voltage Vth is shifted in the negative direction, and therefore, desired off-characteristics are not likely to be achieved. For this reason, the thicknesses of the channel formation layers 70 may, for example, be smaller than or equal to 20 nm.

The middle layers 71 may be thicker than the channel formation layers 70. The thicknesses of the middle layers 71 are not particularly limited, and may, for example, be greater than 20 nm. The thickness of greater than 20 nm can provide a sufficient effect of shifting the threshold voltage Vth of the TFT 101 in the positive direction. On the other hand, if the middle layers 71 are excessively thick, the threshold voltage Vth is likely to conversely decrease. For this reason, the thicknesses of the middle layers 71 may, for example, be smaller than or equal to 80 nm.

The thickness of the entire semiconductor layer 7 is not particularly limited, and may, for example, be between 30 nm and 120 nm.

### Production Method for TFT 101

An example production method for the TFT 101 will now be described with reference to FIG. 1.

Initially, the gate electrode 3 is formed on the substrate 1. Examples of the substrate 1 include a glass substrate, a silicon substrate, and a heat-resistant plastic substrate (resin substrate). The gate electrode 3 may be formed of the same conductive film of which a gate line GL is formed (the conductive film is hereinafter referred to as a “gate conductive film”). Here, the gate conductive film (not shown, thickness: 50-500 nm, for example) is formed on the substrate (e.g., a glass substrate) 1 by sputtering, etc. Next, the gate conductive film is patterned to form the gate electrode 3 and the gate line GL. The gate conductive film is, for example, a multilayer film including a Ti film (thickness: 30 nm) as a lower layer and a Cu film (thickness: 300 nm) as an upper layer. Note that the material for the gate conductive film is not particularly limited. Examples of the material for the gate conductive film include metals, such as aluminum (Al), tungsten (W), molybdenum (Mo), tantalum (Ta), chromium (Cr), titanium (Ti), copper (Cu), and alloys and metal nitrides thereof, which can be used as appropriate.

Next, the gate insulating layer 5 is formed on the gate electrode 3. The gate insulating layer 5 may be formed by CVD, etc. Examples of the gate insulating layer 5 include a silicon oxide (SiO₂) layer, a silicon nitride (SiNₓ) layer, a silicon oxide nitride (SiOₓN_{y}; x>y) layer, and a silicon nitride oxide (SiNₓO_{y}; x>y) layer, which can be used as appropriate. The gate insulating layer 5 may have a multilayer structure. For example, a silicon nitride layer, a silicon nitride oxide layer, or the like, may be formed as the lower layer on the substrate 1 in order to prevent or reduce diffusion of impurities, etc., from the substrate 1 into the gate insulating layer 5, and a silicon oxide layer, a silicon oxide nitride layer, or the like, may be formed as the upper layer on that layer in order to ensure insulating properties. Here, used is a multilayer film including a SiO₂ film having a thickness of 50 nm as the upper layer, and a SiNₓ film having a thickness of 300 nm as lower layer. If an oxygen-containing insulating layer (e.g. an oxide layer of SiO₂, etc.) is used as the uppermost layer (i.e., a layer in contact with the oxide semiconductor layer) the gate insulating layer 5, then when oxygen vacancies occur in the semiconductor layer 7, oxygen contained in the oxide layer can compensate for oxygen vacancies, and therefore, oxygen vacancies in the semiconductor layer 7 can be reduced.

Next, on the gate insulating layer 5, formed is the semiconductor layer 7 including the first channel formation layer 70A, the first middle layer 71a, and the second channel formation layer 70B in that order, i.e., the first channel formation layer 70A is closest to the gate insulating layer 5.

The semiconductor layer 7 is formed as follows.

Initially, a first oxide semiconductor film, a middle oxide semiconductor film, and a second oxide semiconductor film are formed by, for example, sputtering in that order, i.e., the first oxide semiconductor film being closest to the gate insulating layer 5, to obtain the oxide semiconductor multilayer film. The oxide semiconductor films have compositions and thicknesses corresponding to the respective ones of the first channel formation layer 70A, the first middle layer 71a, and the second channel formation layer 70B. Each oxide semiconductor film may be either a crystalline oxide semiconductor film or an amorphous oxide semiconductor film.

Here, the first and second oxide semiconductor films are formed by sputtering using a target having an atomic ratio In:Ga:Zn of 5:1:4, for example. As a sputtering gas (atmosphere), a gas mixture including a noble gas atom, such as argon, and an acidic gas can be used. Examples of the acidic gas include O₂, CO₂, O₃, H₂O, and N₂O. Here, a gas mixture including Ar gas and oxygen (O₂) gas is used. The proportion, i.e., partial pressure ratio, of the oxygen gas during film formation by sputtering is, for example, 5-20%. The substrate temperature during film formation is, for example, 27-180° C. The pressure range of gas atmosphere (sputtering pressure) as not limited if plasma discharge can be stably generated, and is, for example, 0.1-3.0 Pa.

The middle oxide semiconductor film formed by sputtering using a target having an atomic ratio In:Ga:Zn of 1:3:2, for example. As a sputtering gas, a gas mixture including Ar gas and oxygen (O₂) gas is used. The proportion, i.e., partial pressure ratio, of the oxygen gas during film formation by sputtering is, for example, higher than 0 and lower than or equal to 20%. The substrate temperature and sputtering pressure during film formation may be the same as those that are used during the formation of the first oxide semiconductor film.

Next, the oxide semiconductor multilayer film is annealed. Here, a thermal treatment is performed in the atmosphere at a temperature of 300-500° C. The duration for which the thermal treatment is performed is, for example, 30 minutes to 2 hours.

Next, after the thermal treatment, the oxide semiconductor multilayer film is patterned to obtain the semiconductor layer 7. The patterning of the oxide semiconductor multilayer film is performed by wet etching using an etchant containing phosphoric acid, nitric acid, and acetic acid, for example. As a result, obtained is the semiconductor layer 7 including the first channel formation layer 70A, the first middle layer 71a, and the second channel formation layer 70B, which are disposed in that order with the first channel formation layer 70A closest to the gate insulating layer 5.

Next, the source electrode 8 and the drain electrode 9 are formed so as to be in contact with an upper surface of the semiconductor layer 7. The source electrode 8 and the drain electrode 9 may have either a monolayer structure or a multilayer structure. The source electrode 8 and the drain electrode 9 may be formed using the same conductive film that is used for a source bus line SL described below (the conductive film is hereinafter referred to as a “source conductive film”). Here, as the source conductive film, a multilayer film is formed which includes two layers, i.e., a Ti film(thickness: 30 nm) and a Cu film (thickness: 300 nm), which are stacked in that order with the Ti film closer to the semiconductor layer 7. Alternatively, three layers, i.e., a Ti film (thickness: 30 nm), an Al film (thickness: 300 nm, and a Ti film (thickness: 50 nm) may be stacked. The source conductive film may be formed by, for example, sputtering.

Next, the source conductive film is patterned to obtain the source electrode 8 and the drain electrode 9 (source-drain separation).

The source electrode 8 is disposed in contact with the source contact region 7s of the semiconductor layer 7. The drain electrode 9 is disposed in contact with the drain contact region 7d of the semiconductor layer 7. In this step, a surface portion of the semiconductor layer 7 (here, a surface portion of the second channel formation layer 70B) may also be etched (overetching). Thereafter, an oxidation treatment, such as a plasma treatment using N₂O gas, may be performed on the channel region of the semiconductor layer 7. Thus, the TFT 101 is obtained.

Next, the upper insulating layer 11 is formed so as to be in contact with the channel region 7c of the TFT 101. The upper insulating layer 11 is, for example, an inorganic insulating layer (passivation film). Examples of the inorganic insulating layer include a silicon oxide (SiO₂) film, a silicon nitride (SiNₓ) film, a silicon oxide nitride (SiOₓN_{y}; x>y) film, and a silicon nitride oxide (SiOₓN_{y}; x>y) film. Here, as the inorganic insulating layer, a SiO₂ layer having a thickness of, for example, 300 nm is formed by CVD. The temperature at which the inorganic insulating layer is formed may be, for example, 200-450° C. Although not shown, an organic insulating layer may be formed on the upper insulating layer 11. As the organic insulating layer, a positive photosensitive resin film having a thickness of 2000 nm may be formed, for example.

### Example and Comparative Examples

In order to verify the effect of the multilayer channel structure of this embodiment, the present inventors produced bottom-gate structure TFTs according to an example and comparative examples, and evaluated characteristics of the TFTs.

In the description that follows, an oxide semiconductor layer that is formed of a composition having a high mobility and therefore is capable of functioning as a channel is referred to as a “high-mobility layer,” and an oxide semiconductor layer that is formed of a composition. having a lower mobility than that of a high-mobility layer is referred to as a “low-mobility layer.”

The TFT of the example is the three-layer channel structure TFT shown in FIG. 1. The semiconductor layer 7, which an In—Ga—Zn—O semiconductor layer, includes the first and second channel formation layers 70A and 70B as high-mobility layers, and the middle layer 71 as a low-mobility layer interposed therebetween.

TFTs comparative examples 1-3 each have a semiconductor layer different from that of the TFT of the example. The TFTs of comparative examples 1-3 are similar, in structure except for their semiconductor layers, to the TFT of the example.

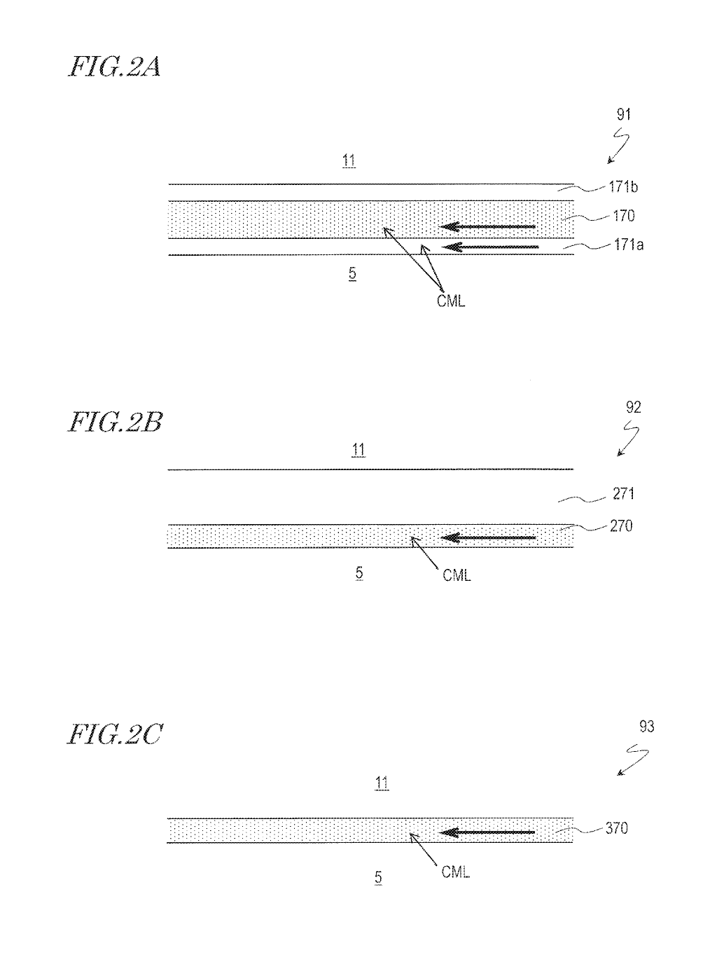

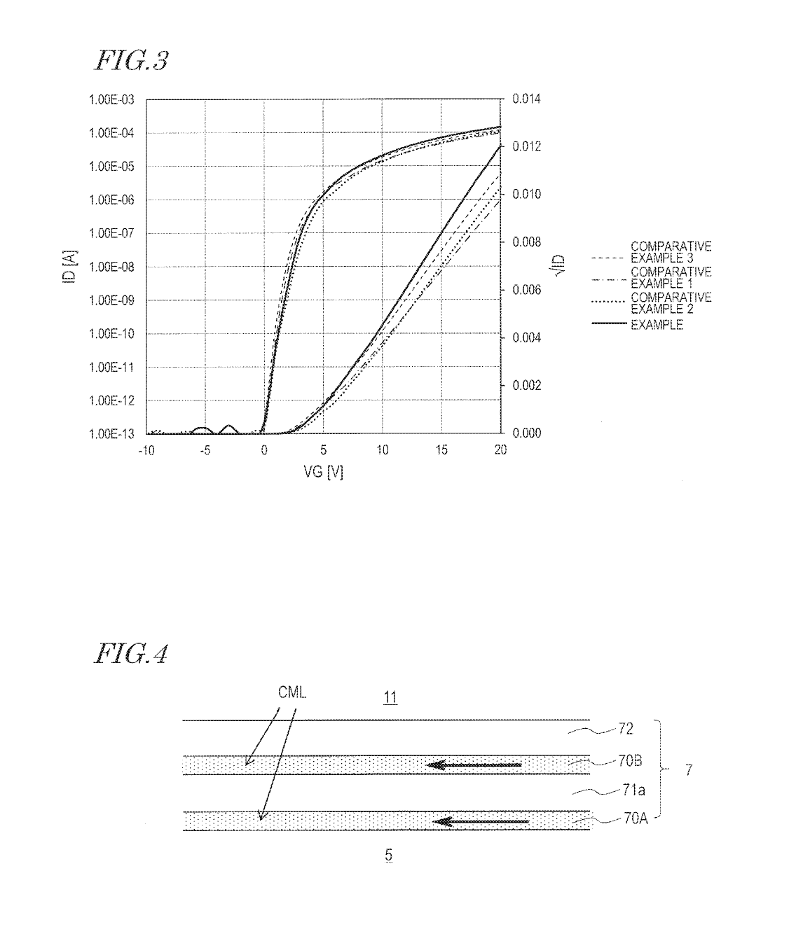

FIGS. 2A-2C are schematic cross-sectional views of semiconductor layers 91, 92, and 93 in the TFTs of comparative examples 1-3, respectively. These semiconductor layers are all an In—Ga—Zn—O semiconductor layer.

In the TFT of comparative example 1, the semiconductor layer 91 has a three-layer structure in which a high-mobility layer 170 is provided as a middle layer, and low-mobility layers 171a and 171b are provided above and below the high-mobility layer 170. Note that such a three-layer structure having a high-mobility layer as a middle layer is described in, for example, Japanese Laid-open Patent Publication No. 2014-033194.

In the TFT of comparative example 2, the semiconductor layer 92 has a two-layer structure in which a high-mobility layer 270 and a low-mobility layer 271 are stacked in that order on the gate insulating layer 5 with the high-mobility layer 270 closer to the gate insulating layer 5. Such a two-layer structure is described in, for example, Japanese Laid-open Patent Publication No. 2013-41945.

In the TFT of comparative example 3, the semiconductor layer 93 has a monolayer structure having a high-mobility layer 370.

The composition and thickness of each layer in the semiconductor layers of the example and comparative examples 1-3 are shown in Table 1.

TABLE 1

| | | | Compar- | Compar- | Compar- |
|---|---|---|---|---|---|
| | | | ative | ative | ative |
| | | Example | example 1 | example 2 | example 3 |
| Structure of semi- | | 3-layer | 3-layer | 2-layer | 1-layer |
| conductor layer | | structure | structure | structure | structure |
| Upper | In:Ga:Zn | 5:1:4 | 1:3:2 | 1:3:2 | — |
| laylar | Thickness | 10 nm | 10 nm | 40 nm | |
| Middle | In:Ga:Zn | 1:3:2 | 5:1:4 | — | — |
| Laylar | Thickness | 40 nm | 20 nm | | |
| Lower | In:Ga:Zn | 5:1:4 | 1:3:2 | 5:1:4 | 5:1:4 |
| laylar | Thickness | 10 nm | 10 nm | 20 nm | 20 nm |

| | | | | |
|---|---|---|---|---|
| Threshold voltage Vth | 2.3 | 2.0 | 2.5 | 1.8 |
| [V] | | | | |
| TFT mobility μ [cm²/Vs] | 12.0 | 7.3 | 9.2 | 9.2 |

Next, results of evaluation of the TFTs of the example and the comparative examples will be described.

FIG. 3 is a diagram illustrating VG (gate-source voltage)-ID (drain current) characteristics of each of the TFTs of the example and the comparative examples. Results of measurement of the threshold voltage Vth and TFT mobility μ of each of the TFTs of the example and the comparative examples are also shown in Table 1. Note that the TFT mobility μ is the mobility of the entire multilayer semiconductor layer.

As can be seen from Table 1, the TFT mobility μ of the TFT of the example is higher than those of comparative examples 1-3. A reason for this result is considered as follows.

As shown in FIG. 2A, in the TFT of comparative example 1, carriers flow through the low-mobility layer 171a disposed closest to the gate insulating layer, or are distributed and accumulated in the low-mobility layer 171a and the high-mobility layer 170. Because carriers moves in the low-mobility layer 171a, the mobility μ of the TFT of comparative example 1 is considered to be significantly reduced compared to the TFT mobilities of the example and comparative examples 2 and 3, in which the high-mobility layer functions as a carrier movement layer CML.

On the other hand, as shown in FIG. 2B, in the TFT of comparative example 2, carrier flow through the high-mobility layer 270 disposed on the gate insulating layer, and therefore, the high-mobility layer 270 functions as a carrier movement layer CML. As shown in FIG. 2C, in the TFT of comparative example 3, the high-mobility layer 370 functions as a carrier movement layer CML. The TFTs of comparative examples 2 and 3 each include a single carrier movement layer CML.

In contrast to this, in the TFT of the example, the two high-mobility layers, i.e., the first channel formation layer 70A and the second channel formation layer 70B, function as a carrier movement layer CML (see FIG. 1B). Therefore, compared to when only a single high-mobility layer is provided (comparative examples 2 and 3), the number of carriers flowing through the carrier movement layers CML may increase, and therefore, the on-current (TFT mobility μ) is improved. Specifically, the mobility μ of the TFT of the example is higher by about 30% than the TFT mobilities μ of comparative examples 2 and 3.

The TFTs of the example and comparative examples 1 and 2 have a higher (more positive) threshold voltage Vth than that of the TFT of comparative example 3. This result demonstrates that the threshold voltage Vth is shifted in the positive direction by providing a low-mobility layer in the semiconductor layer. In particular, in the TFTs of the example and comparative example 2, the semiconductor layers 7 and 92 include the low-mobility layers 71a and 271, which are relatively thick, and therefore, a higher threshold voltage Vth is obtained. On the other hand, in the TFT of comparative example 1, the low-mobility layers 171a and 171b are thin, and therefore, the effect of shifting the threshold voltage Vth in the positive direction may be insufficient. Although the threshold voltage Vth can be increased by increasing the thicknesses of the low-mobility layers 171a and 171b in the semiconductor layer 91 of comparative example 1, the number of carriers flowing through the low-mobility layer 171a may increase, and therefore, the TFT mobility μ may further decrease.

Therefore, the above results demonstrate that in the TFT of the example, the threshold voltage Vth can be controlled to a desired positive voltage, and the TFT mobility μ can be improved compared to the TFTs of comparative examples 1-3.

### Variations

The semiconductor layer 7 may further include a layer in addition to the channel formation layers 70 and the middle layers 71. For example, in the case where the TFT 101 has a channel-etch structure, an oxide semiconductor layer that functions as a protective layer (also called a “sacrificial layer”) may be formed as the uppermost layer of the semiconductor layer 7.

FIG. 4 is an enlarged cross-sectional view showing a variation of the semiconductor layer 7. In FIG. 4 and those following it, parts similar to those of FIG. 1 are indicated by the same reference characters and will not be described in detail.

In the semiconductor layer 7 of FIG. 4, a protective layer 72 for protecting the second channel formation layer 70B is provided between the second channel formation layer 70B and the upper insulating layer 11. The upper surface of the protective layer 72 may be in contact with the upper insulating layer 11.

The protective layer 72 is, for example, an oxide semiconductor layer having a lower mobility than that of the channel formation layer 70. The composition and thickness of the protective layer 72 may, for example, be the same as those of the middle layers 71.

If the protective layer 72 is provided on the second channel formation layer 70B, process damage to the second channel formation layer 70B can be reduced in the source-drain separation step, for example. Therefore, variations in the TFT characteristics, negative shift of the threshold voltage, etc., can be prevented or reduced, whereby superior reliability can be imparted to the TFT 101.

FIG. 1 illustrates an example in which the semiconductor layer 7 of the TFT 101 has the two channel formation layers 70. Alternatively, the semiconductor layer 7 including three or more channel formation layers 70 may be formed by alternately stacking the channel formation layers 70 and middle layers 71.

FIGS. 5A and 5B are enlarged cross-sectional views showing other variations of the semiconductor layer 7.

In the example of FIG. 5A, the multilayer structure of the semiconductor layer 7 is different from that of the TFT 101 of FIG. 1 in that the semiconductor layer 7 further includes a third channel formation layer 70C and a second middle layer 71b. The third channel formation layer 70C is disposed on an opposite side (here, closer to the upper insulating layer 11) of the second channel formation layer 70B from the first middle layer 71a The second middle layer 71b is disposed between the second channel formation layer 70B and the third channel formation layer 70C.

The first channel formation layer 70A, the second channel formation layer 70B, and the third channel formation layer 70C of the semiconductor layer 7 function as a carrier movement layer CML. The three channel formation layers 70 thus formed in the semiconductor layer 7 can further improve the on-current compared to the case where two channel formation layers 70 are provided (FIG. 1).

Likewise, a semiconductor layer having four or more channel formation layers 70 can be formed, although not shown.

As shown in FIG. 5B, a protective layer 72 may be provided as the uppermost layer of the semiconductor layer 7 (here, on the third channel formation layer 70C). As described above with reference to FIG. 4, the protective layer 72 is an oxide semiconductor layer having a lower mobility than that of the channel formation layer 70.

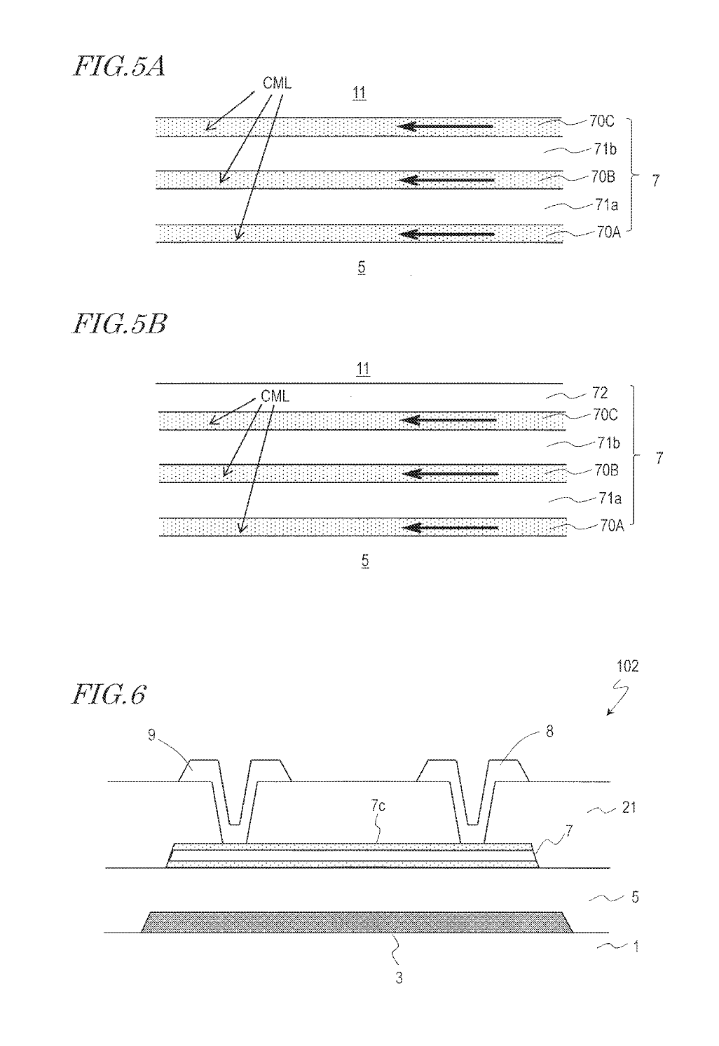

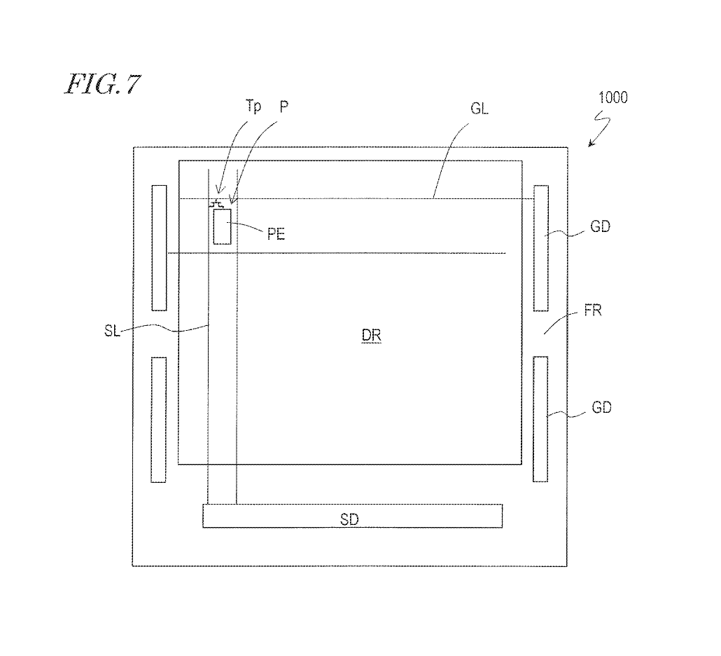

FIG. 6 is schematic cross-sectional view illustrating another TFT 102 according to this embodiment. The TFT 102 is an etch-stop TFT.

As shown in FIG. 1, in the channel-etch TFT 101, an etch-stop layer is not formed on the channel region 7c, and the lower surfaces of end portions closer to the channel of the source electrode 8 and the drain electrode 9 are disposed in contact with the upper surface of the semiconductor layer 7.

In contrast to this, as shown in FIG. 6, in the etch-stop TFT 102, an etch-stop layer (channel protective layer) 21 is formed on the channel region 7c. The lower surfaces of end portions closer to the channel of the source electrode 8 and the drain electrode 9 are disposed on the etch-stop layer 21, for example. The source electrode 8 and the drain electrode 9 are in contact with the source contact region 7s and the drain contact region 7d, respectively, of the semiconductor layer 7 in respective openings formed in the etch-stop layer 21. The etch-stop layer 21 is not particularly limited, and may, for example, be a silicon oxide layer, a silicon nitride layer, a silicon oxide nitride layer, etc. (thickness: for example, 30-200 nm).

The etch-stop TFT 102 is formed by, for example, forming the etch-stop layer 21 covering a portion of the semiconductor layer 7 that is subsequently treated to form a channel region, forming a conductive film for source and drain electrodes on the semiconductor layer 7 and the etch-stop layer 21, and performing source-drain separation. In the TFT 102, the etch-stop layer 21 can reduce process damage to the uppermost layer of the semiconductor layer 7. Therefore, even if a channel formation layer 70 is disposed as the uppermost layer without providing the protective layer 72, a deterioration in characteristics due to process damage can be prevented or reduced.

### Structure of Active Matrix Substrate

This embodiment may be applied to, for example, an active matrix substrate for a display device. In the case where this embodiment is applied to an active matrix substrate, at least a portion of a plurality of TFTs provided in the active matrix substrate are the TFT 101 or 102 having the above multilayer channel structure. For example, a pixel TFT disposed at each pixel and/or a TFT (circuit TFT) included in a monolithic driver may have the multilayer channel structure.

A configuration of the active matrix substrate will now be described with reference to the drawings.

FIG. 7 is a schematic diagram showing an example two-dimensional structure of an active matrix substrate 1000 according to this embodiment.

The active matrix substrate 1000 has a display region DR, and a region (a non-display region or a frame region) FR other than the display region DR. The display region DR includes pixel regions P arranged in a matrix. The pixel regions P correspond to pixels of a display device, and may also be simply referred to as “pixels.” Each pixel region P has a thin-film transistor Tp that is a pixel TFT, and a pixel electrode PE. Although not shown, in the case where the active matrix substrate 1000 is applied to a display device that operates in a horizontal electric field mode, such as the fringe field switching (FFS) mode, the active matrix substrate 1000 is provided with a common electrode facing the pixel electrode PE with an insulating layer (dielectric layer) interposed therebetween.

The non-display region FR is disposed around the display region DR, and is a region where an image is not displayed. The non-display region FR includes a terminal formation region in which terminals are formed, a drive circuit formation region in which a drive circuit is integrally (monolithically) formed, etc. In the drive circuit formation region, for example, a gate driver GD, a test circuit (not shown), etc., are monolithically provided. A source driver SD is mounted on, for example, the active matrix substrate 1000. In the display region DR, a plurality of gate lines GL extending in the row direction, and a plurality of source bus lines SL extending in the column direction, are provided. Pixels are, for example, delimited by the gate lines GL and the source bus lines SL. The gate lines GL are coupled to respectively corresponding terminals of the gate driver GD. The source bus lines SL are coupled to respectively corresponding terminals of the source driver SD mounted on the active matrix substrate 1000.

### Configuration of Pixel Region P

Next, a configuration of each pixel region P in the active matrix substrate 1000 will be described. Here, it is assumed that the active matrix substrate is applied to an FFS-mode LCD panel, for example.

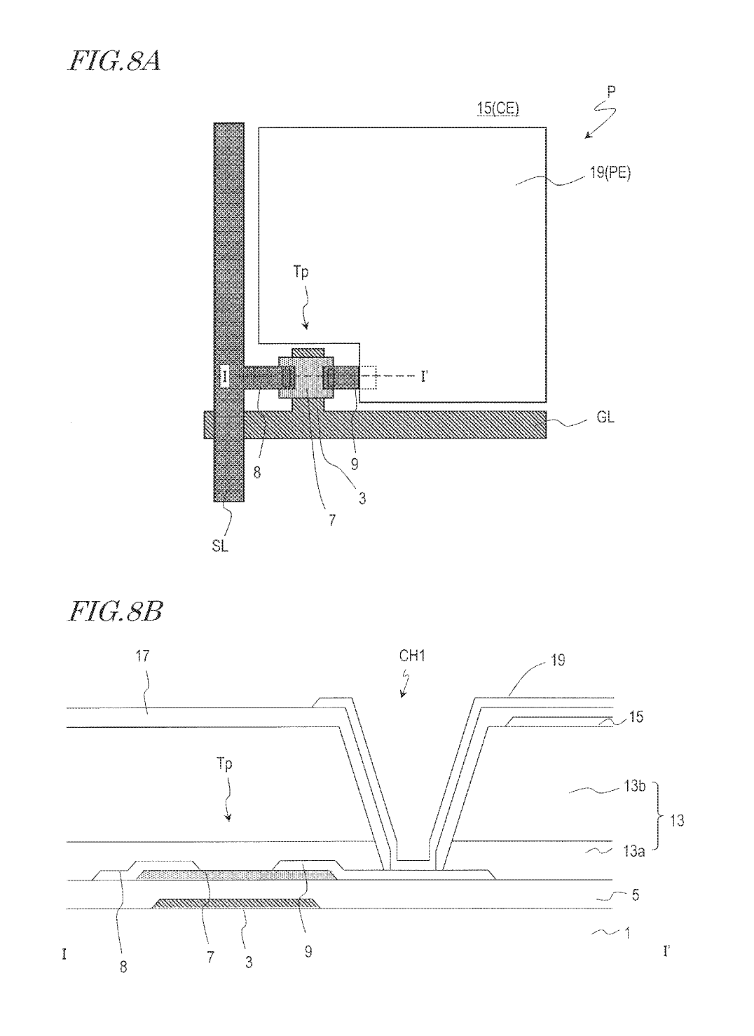

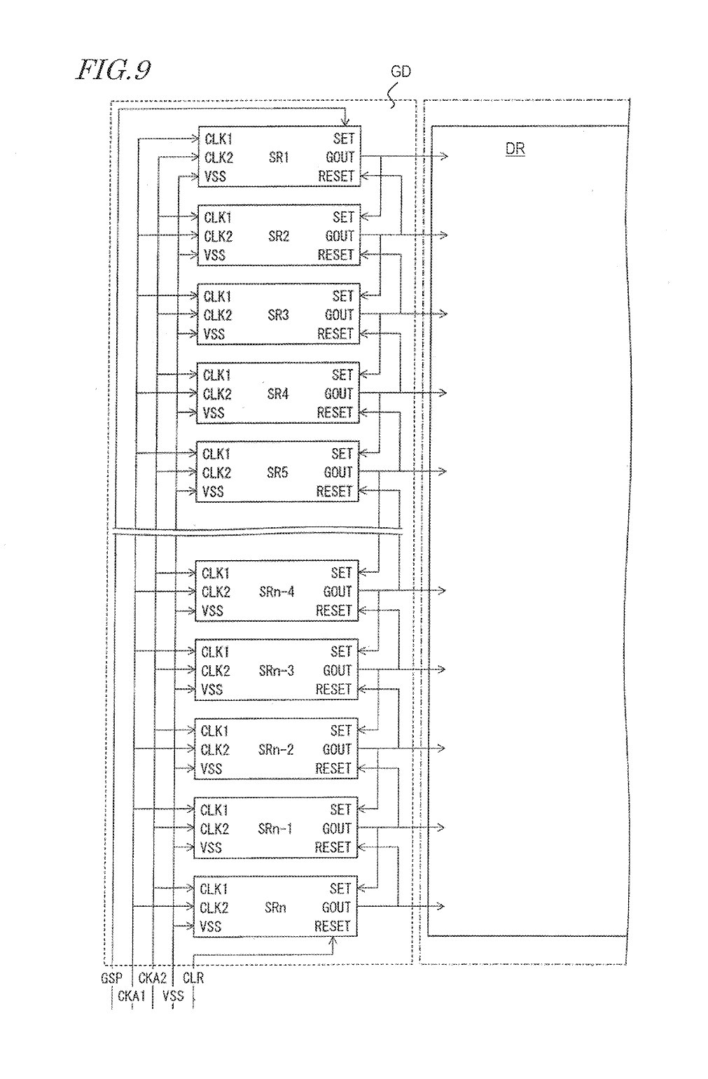

FIGS. 8A and 8B are a plan view of one pixel region P in the active matrix substrate 1000, and a cross-sectional view thereof taken along line I-I′, respectively.

The pixel region P is surrounded by a source bus line SL and a gate line GL extending in a direction intersecting that source bus line SL. The pixel region P has a substrate 1, a thin-film transistor (pixel TFT) Tp supported by the substrate 1, a lower transparent electrode 15, and an upper transparent electrode 19. In this example, the lower transparent electrode 15 is a common electrode CE, and the upper transparent electrode 19 is a pixel electrode PE. Alternatively, the lower transparent electrode 15 may be a pixel electrode PE, and the upper transparent electrode 19 may be a common electrode CE.

The thin-film transistor Tp may be any of the multilayer channel structure TFTs shown in FIGS. 1 and 4-6. FIG. 8B illustrates the channel-etch TFT of FIG. 1 as the thin-film transistor Tp.

The gate electrode 3 of the thin-film transistor Tp is coupled to the corresponding gate line GL, and the source electrode 8 of the thin-film transistor Tp is coupled to the corresponding source bus line SL. The drain electrode 9 is electronically connected to the pixel electrode PE. The gate electrode 3 and the gate line GL may be integrally formed using the same conductive film. The source electrode 8, the drain electrode 9, and the source bus line SL may be integrally formed using the same conductive film.

An interlayer insulating layer 13 is not particularly limited, and may, for example, include an inorganic insulating layer (passivation film) 13a, and an organic insulating layer 13b provided on the inorganic insulating layer 13a. Note that the interlayer insulating layer 13 may not include the organic insulating layer 13b.

The pixel electrode PE and the common electrode CE overlaps each other with the dielectric layer 17 interposed therebetween. A separate pixel electrode PE is provided for each pixel. It is not necessary to provide a separate common electrode CE for each pixel, i.e., the common electrode CE is common to all pixels. In this example, the common electrode CE is provided on the interlayer insulating layer 13. The pixel electrode PE is provided on the dielectric layer 17, and is electronically connected to the drain electrode 9 in an opening CH1 provided in the interlayer insulating layer 13 and the dielectric layer 17. Although not shown, the pixel electrode PE has at least one slit or notch for each pixel. The common electrode CE may be provided throughout the pixel region P, except for a region where the opening CH1 is formed.

The pixel electrode PE and the common electrode CE may each be formed of, for example, an ITO (indium tin oxide) film, an In—Zn—O oxide (indium zinc oxide) film, or a ZnO film (zinc oxide film). The pixel electrode PE and the common electrode CE may each have a thickness of, for example, 50-200 nm. The dielectric layer 17 may, for example, be a silicon nitride (SiNₓ) film, a silicon oxide (SiOₓ) film, a silicon oxide nitride (SiOₓN_{y}; x>y) film, or a silicon nitride oxide (SiNₓO_{y}; x>y) film. The dielectric layer 17 may have a thickness of, for example, 70-300 nm.

The active matrix substrate 1000 thus configured may be applied to, for example, an FFS-mode display device. The FFS mode is a horizontal electric field mode in which a pair of electrodes (the pixel electrode PE and the common electrode CE) are provided on one of two substrates, and an electric field is applied to liquid crystal molecules in a direction (horizontal direction) parallel to the substrate surface.

An electrode structure in which the pixel electrode PE is provided above the common electrode CE with the dielectric layer 17 interposed therebetween is described in, for example. International Publication WO2012/086513. An electrode structure in which the common electrode CE is provided above the pixel electrode PE with the dielectric layer 17 interposed therebetween is described in, for example, Japanese Laid-open Patent Publication Nos. 2008-032899 and 2010-008758. The entire contents of International Publication WO2012/086513 and Japanese Laid-Open Patent Publication Nos. 2008-032899 and 2010-008758 are hereby incorporated by reference.

### Drive Circuit

Next, a configuration of a drive circuit that is integrally formed in the active matrix substrate 1000 will be described using the gate driver GD as an example. The gate driver GD includes a shift register. The shift register includes a plurality of unit circuits that are connected in a cascade.

FIG. 9 is a diagram illustrating a shift register circuit included in the gate driver (monolithic gate driver) GD.

The shift register circuit has a plurality of unit circuits SR1-SRn. A unit circuit SRk (k is a natural number of 1≤k≤n) in each stage has a set terminal which receives a set signal SET, an output terminal which outputs an output signal GOUT, a reset terminal which receives a reset signal RESET, a low power supply input terminal which receives a low power supply potential VSS, and clock input terminals which receives clock signals CLK1 and CLK2. The set terminal of the unit circuit SRk (k≥2) receives the output signal GOUTk-1 of the previous-stage unit circuit SRk-1. The set terminal of the first-stage unit circuit SR1 receives a gate start pulse signal GSP. The output terminal of the unit circuit SRk (k≥1) in each stage outputs the output signal GOUTk to a corresponding scan signal line provided in the display region. The reset terminal of the unit circuit SRk (k≤n−1) receives the output signal GOUTk+1 of the next-stage unit circuit SRk+1. The reset terminal of the final-stage unit circuit SRn receives a clear signal CLR.

The low power supply input terminal of each unit circuit SRk receives the low power supply potential VSS that is a power supply voltage having a lower potential. One of the two clock input terminals receives the clock signal CLK1, and the other receives the clock signal CLK2. The clock signals CLK1 and CLK2 are input to the clock input terminal in alternate stages. The clock signals CLK1 and CLK2 have a complimentary phase relationship so that their active clock pulse periods (here, high-level periods) do not overlap. The high-level (active) voltage of the clock signals CLK1 and CLK2 is VGH, and the low-level (inactive) voltage of the clock signals CLK1 and CLK2 is VGL. The low power supply voltage VSS is equal to the low-level voltage VGL of the clock signals CLK1 and CLK2. The gate start pulse signal GSP is active during the first clock pulse period of each frame period. The clear signal CLR is active (here, high) during the final clock pulse period of each frame period.

In the shift register circuit, at the beginning of each frame period, the gate start pulse signal GSP is input as a shift pulse to the set terminal of the first-stage unit circuit SR1. In the shift register circuit, the shift pulse is transferred sequentially from one stage to another of the unit circuits SRk connected in a cascade, so that the active pulses of the output signals GOUTk are output.

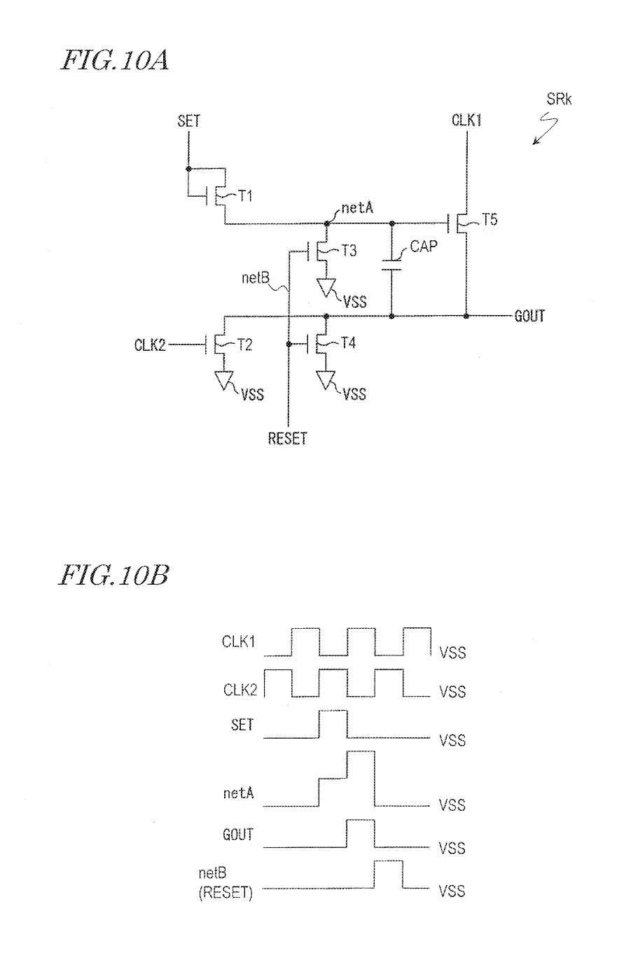

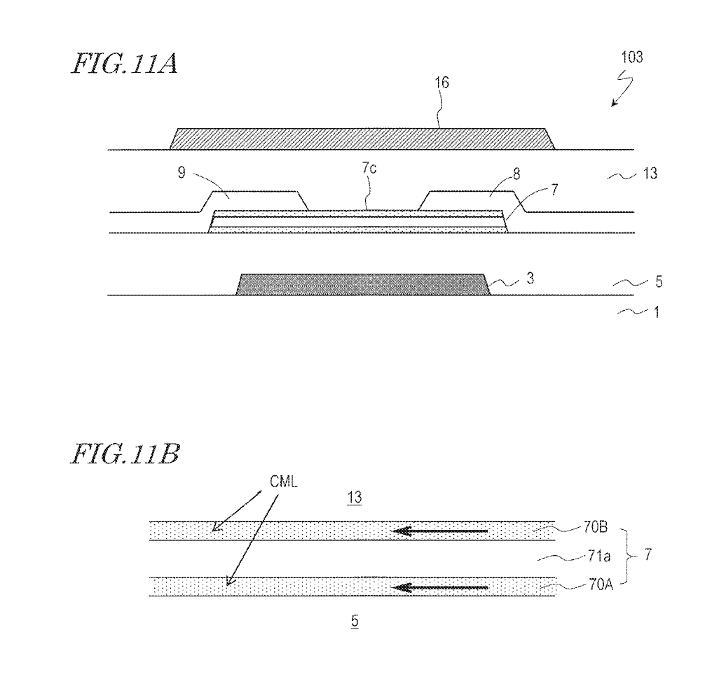

FIG. 10A is a diagram showing an example of the unit circuit SRk. FIG. 10B is a diagram showing a signal waveform in the unit circuit SRk.

The unit circuit SRk includes five n-channel thin-film transistors T1-T5 and a capacitor CAP.

All or a portion of the thin-film transistors T1-T5 may have the above multilayer channel structure. Of these thin-film transistors, the thin-film transistor T5 is required to have particularly great current drive power, and has a large TFT size (channel width). Therefore, the multilayer channel structure of this embodiment is advantageously applied to at least the thin-film transistor T5.

The thin-film transistor T1 is an input transistor. The gate and drain of the thin-film transistor T1 are coupled to the set terminal, and the source of the thin-film transistor T1 is coupled to the gate of the thin-film transistor T5. The thin-film transistor T5 is an output transistor. The drain and source of the thin-film transistor T5 are coupled to a clock input terminal and the output terminal, respectively. In other words, the thin-film transistor T5 functions as a transfer gate to pass and block the clock signal CLK1 input to the clock input terminal.

The capacitor (bootstrap capacitor) CAP is coupled between the gate and source of the thin-film transistor T5 as an output transistor. A node coupled to the gate of the thin-film transistor T5 is referred to as a “node netA,” and a node coupled to the output terminal is referred to as a “node GOUT.” One electrode of the capacitor CAP is coupled to the gate of the thin-film transistor T5 and the node netA, and the other electrode is coupled to the source of the thin-film transistor T5 and the node GOUT.

The thin-film transistor T3 is disposed between the low power supply input terminal and the node netA. The thin-film transistor T3 is a pull-down transistor for reducing the potential of the node netA. The gate, drain, and source of the thin-film transistor T3 are coupled to the reset terminal, the node netA, and the low power supply input terminal, respectively. A node coupled to the gate of a pull-down transistor (here the thin-film transistor T3) is referred to as a “node netB.”

The thin-film transistors T2 and T4 are coupled to the node GOUT. The gate, drain, and source of the thin-film transistor T4 are coupled to the reset terminal, the output terminal, and the low power supply input terminal, respectively. The gate, drain, and source of the thin-film transistor T2 are coupled to the input terminal for the clock signal CLK2, the node GOUT, and the low power supply input terminal, respectively.

In the unit circuit SRk, during a period of time until a shift pulse is input to the set terminal, the thin-film transistors T4 and T5 are in the high-impedance state, the thin-film transistor T2 is turned on each time the clock signal CLK2 input through the clock input terminal goes high, and the output terminal is kept low.

As shown in FIG. 10B, when a shift pulse is input to the set terminal, a period of time during which a gate pulse that is an active pulse of the output signal GOUT is generated is started, and the thin-film transistor T1 is turned on, so that the capacitor CAP is charged. When the capacitor CAP is charged, the potential V_{(netA)} of the node netA increases up to VGH−Vth (V_{(netA)}=VGH−Vth), where VGH represents the high level of the gate pulse, and Vth represents the threshold voltage of the thin-film transistor T1. As a result, the thin-film transistor T5 is turned on, and the clock signal CLK1 input through the clock input terminal appears at the source of the thin-film transistor TFT 35. When this clock pulse (high level) has just been input, the potential of the node netA suddenly increases due to the bootstrap effect of the capacitor CAP, and therefore, the thin-transistor T5 obtains a great overdrive voltage. As a result, substantially the entire amplitude VGH of the clock pulse input to the clock input terminal is transferred to the output terminal, and is output as a gate pulse.

When the input of the shift pulse to the set terminal ends, the thin-film transistor T1 is turned off, and the node netA is kept in the floating state. After the end of the gate output (GOUT), the floating state of each node is removed by a reset pulse signal. Specifically, the gate pulse of the next-stage unit circuit SRk+1 is input as a reset pulse to the reset terminal. As a result, the thin-film transistors T3 and T4 are turned on, so hat the node netA and the output terminal are connected to the low power supply voltage VSS. Therefore, the thin-film transistor T5 is turned off. When the input of the reset pulse ends, the gate pulse generation period of the unit circuit SRk ends, and a period of time during which the output terminal is kept low starts again.

### Second Embodiment

A semiconductor device according to a second embodiment includes a TFT having a dual-gate structure in which two gate electrodes are provided with an oxide semiconductor layer interposed therebetween.

FIG. 11A is a cross-sectional view of a TFT 103 according to this embodiment. FIG. 11B is an enlarged cross-sectional view of a semiconductor layer 7 included in the TFT 103.

The TFT 103 has a multilayer channel structure in which the semiconductor layer 7, which functions as an active layer, includes channel formation layers 70 and a middle layer(s) 71. Although, in the example of FIG. 11B, the semiconductor layer 7 has a three-layer structure, the semiconductor layer 7 may have a multilayer structure including five or more layers as shown in FIG. 5A.

The TFT 103 is different from the TFT 101 of FIG. 1 in that an upper electrode 16 is provided on the semiconductor layer 7 with an interlayer insulating layer 13 therebetween. The upper electrode 16 is disposed so as to face at least the channel region 7c of the semiconductor layer 7 with the interlayer insulating layer 13 interposed therebetween. The interlayer insulating layer 13 functions as a gate insulating layer (also referred to as an upper gate insulating layer).

The upper electrode 16 may be grounded (fixed to the GND potential). As a result, characteristics of TFT 31 can be reliably stabilized. The upper electrode 16 may be connected to the source electrode 8 by a contact portion (not shown). Alternatively, the gate electrode 3 may be electronically connected to the upper electrode 16.

The upper electrode 16 may, for example, be a transparent electrode formed of the same transparent conductive film of which the pixel electrode PE or the common electrode CE is formed. Alternatively, the upper electrode 16 may be a metal electrode. For example, in the case where a metal auxiliary interconnect having a low resistance is provided in order to assist the common electrode CE, the upper electrode 16 may be formed of the same metal film of which the metal auxiliary interconnect is formed.

The interlayer insulating layer 13 may be an inorganic insulating layer similar to the upper insulating layer 11 of FIG. 1. As illustrated in FIG. 8B, the interlayer insulating layer 13 may have a multilayer structure including an inorganic insulating layer 13a and an organic insulating layer 13b provided thereon.

In the TFT 103 of this embodiment, when a predetermined voltage is applied to each of the gate electrode 3 and the upper electrode 16, the channel formation layers 70 in the semiconductor layer 7 function as a carrier movement layer CML. In this embodiment, not only is the first channel formation layer 70A, which is the lowermost semiconductor layer 7, in contact with the gate insulating layer 5, but also the second channel formation layer 70B, which is the uppermost layer, is in contact the interlayer insulating layer 13, which functions as a lower gate insulating layer. Therefore, compared to the TFT 101, carriers flowing through the second channel formation layer 70B can be increased, resulting in an increase in the on-current.

In this embodiment, not only the lowermost layer (closer to the gate insulating layer 5) but also as the uppermost layer (closer to the interlayer insulating layer 13) of the semiconductor layer 7 are preferably a channel formation layer 70. Thus, one of the channel formation layers 70 is preferably the uppermost layer of the semiconductor layer 7 and is in contact with the interlayer insulating layer 13. If another semiconductor layer (e.g., the protective layer 72 of FIG. 4) is provided between the channel formation layer 70 and the interlayer insulating layer 13, a portion of carriers are likely to flow through the protective layer 72. In contrast to this, if the channel formation layer 70 is disposed in contact with the interlayer insulating layer 13, most carriers flow through the channel formation layer 70, and therefore, the on-current can be effectively increased.

Note that in the TFTs of comparative examples 1 and 2, a low-mobility layer is provided on the interlayer insulating layer 13, which functions as an upper gate insulating layer, and therefore, the effect of improving the on-current using an upper electrode is reduced. In contrast to this, in this embodiment, a channel formation layer 70 (here, the second channel formation layer 70B) is disposed in contact with the interlayer insulating layer 13, and therefore, the on-current can be further increased by utilizing the upper electrode 16.

The TFT of this embodiment may be used as a pixel TFT and/or a circuit TFT in the active matrix substrate described above with reference to FIGS. 7-10.

An example will now be described in which the dual-gate structure TFT of this embodiment is applied to a circuit TFT (e.g., the output transistor T5 (see FIG. 10)) included in a gate driver.

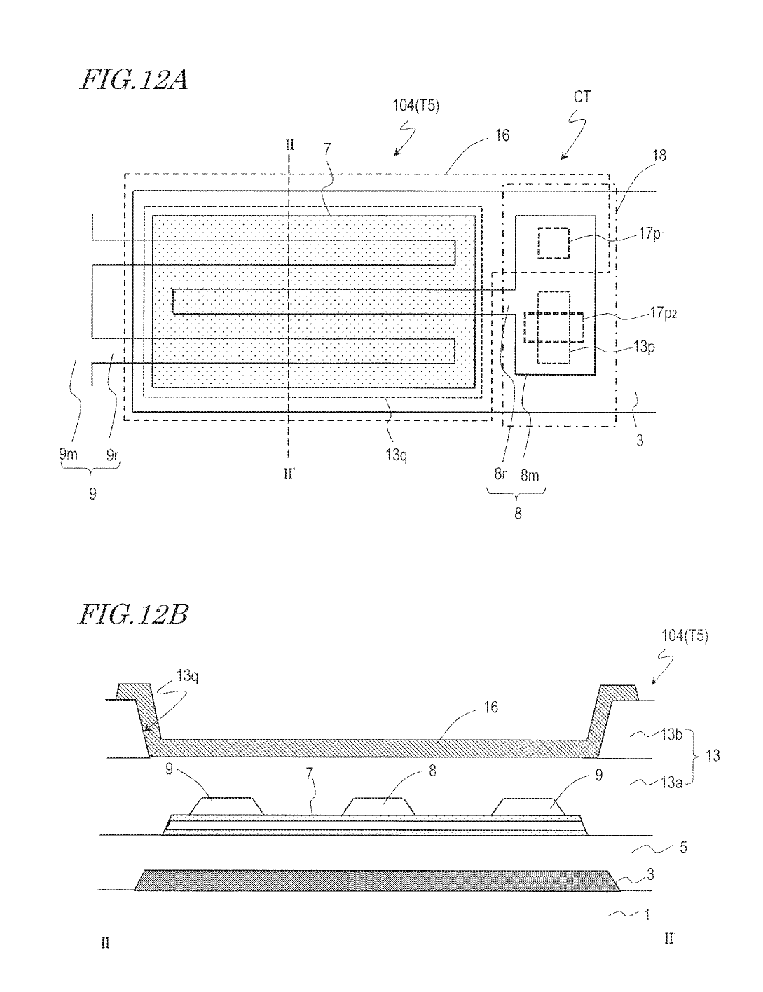

FIG. 12A is a plan view illustrating an output transistor T5 included in a gate driver. FIG. 12B is a cross-sectional view of the output transistor T5 taken along line II-II′ of FIG. 12A.

A TFT 104 that functions as the output transistor T5 is configured to have a greater channel width than those of the other circuit TFTs. Here, the source electrode 8 and the drain electrode 9 of the output transistor T5 have a so-called structure. For example, the source electrode 8 and the drain electrode 9 each have main portions 8m and 9m extending in a first direction, and one or more branch portions (comb-tooth portions) 8r and 9r extending from the main portions 8m and 9m in a second direction intersecting the first direction, respectively. The source electrode 8 and the drain electrode 9 are disposed so as to face each other with the comb tooth portions 8r and 9r interdigitated.

An opening 13q may be provided in the organic insulating layer 13b of the interlayer insulating layer 13 above the TFT 104. The region of the opening 13q may overlay at least a portion of the semiconductor layer 7 that is a channel region, as viewed in the direction of the normal to the substrate 1. As a result, only the inorganic insulating layer 13a can function as an upper gate insulating layer.

The upper electrode 16 is connected to the main portion 8m of the source electrode 8 at a contact portion CT. In this example, the pixel electrode PE is an upper transparent electrode, and the common electrode CE is a lower transparent electrode. The upper electrode 16 is formed (i.e., in a lower transparent conductive layer) of the same transparent conductive film of which the common electrode CE is formed. At the contact portion CT, the upper electrode 16 is electronically connected to the source electrode 8 by an island-shaped transparent connection portion 18 formed (i.e., in an upper transparent conductive layer) of the same transparent conductive film of which the pixel electrode PE is formed. Specifically, the transparent connection portion 18 is in contact with the upper electrode 16 in an opening 17p₁ formed in the dielectric layer 17, and is in contact with the source electrode 8 in an opening 17p₂ formed in the dielectric layer 17 and an opening 13p formed in the interlayer insulating layer 13.

Note that the structures of the thin-film transistor T5 and the contact portion CT are not limited to the illustrated example. For example, the upper electrode 16 may be formed in the lower transparent conductive layer. In this case, the upper electrode 16 may be in contact with the source electrode 8 in an opening formed in the interlayer insulating layer 13 at the contact portion CT.

### Third Embodiment

A semiconductor device according to a third embodiment has a TFT having a top-gate structure in which the gate electrode is provided on an opposite side of the semiconductor layer from the substrate.

FIG. 13A is a cross-sectional view of a TFT 105 according to this embodiment. FIG. 13B is an enlarged cross-sectional view of a semiconductor layer 7 of the TFT 105.

The TFT 105 has a semiconductor layer 7, a gate insulating layer 30, a gate electrode 32, a source electrode 28, and a drain electrode 29.

The semiconductor layer 27 is formed on a substrate 1. The semiconductor layer 27 may be provided on a lower insulating layer 25 provided on the substrate 1. The semiconductor layer 27 may include an In—Ga—Zn—O semiconductor, for example.

The semiconductor layer 27 has a multilayer structure similar to that of the semiconductor layer 7 described in the above embodiments. Here, the semiconductor layer 27 has a three-laver structure in which a second channel formation layer 70B, a middle layer 71, and a first channel formation layer 70A are stacked on the lower insulating layer 25 in that order (i.e., the semiconductor layer 27 includes the first channel formation layer 70A, the middle layer 71, and the second channel formation layer 70B in that order with the first channel formation layer 70A closest to the gate insulating layer 30). The first channel formation layer 70A is in contact with the gate insulating layer 30. As a result, like the above embodiment, the two layers, i.e., the first and second channel formation layers 70A and 70B, function as a carrier movement layer CML, and therefore, the on-current can be increased. Although not shown, the semiconductor layer 27 may have a multilayer structure including five layers or more (see FIG. 5). In addition to the channel formation layers 70 and the middle layer 71, another oxide semiconductor layer may be provided on a side closer the substrate 1 of the second channel formation layer 70B.

The gate insulating layer 30 is provided on a portion of the semiconductor layer 27. The gate insulating layer 30 may be in the shape of an island and may be provided only in a region directly below the gate electrode 32. The gate electrode 32 is provided on the gate insulating layer 30. The gate electrode 32 faces the semiconductor layer 27 with the gate insulating layer 30 interposed therebetween.

The semiconductor layer 27, the gate insulating layer 30, and the gate electrode 32 are covered by an interlayer insulating layer 35. The source electrode 28 and the drain electrode 29 are disposed on the interlayer insulating layer 35, and are connected to the semiconductor layer 27 in contact holes formed in the interlayer insulating layer 35.

In the process of producing the TFT 105 of this embodiment, a source-drain separation step is performed with the semiconductor layer 27 protected by the gate insulating layer 30, the gate electrode 32, and the interlayer insulating layer 35. Therefore, the first channel formation layer 70A, which is the uppermost layer of semiconductor layer 27, is less likely to suffer from process damage. Therefore, the mobilities of all channel formation layers 70 including the first channel formation layer 70A can be more reliably increased, and therefore, the on-characteristics can be more effectively improved by the multilayer channel structure.

### Production Method for TFT 105

The TFT 105 may be formed as follows, for example. Initially, the semiconductor layer 27 having a three-layer structure is formed on the insulating layer (e.g., a SiO₂ layer) 25. The semiconductor layer 27 may be formed by a method similar to that for the semiconductor layer 7 of the TFT 101.

Next, a gate insulating film and an upper gate conductive film are formed so as to cover the semiconductor layer 27. Examples of the gate insulating film include a silicon oxide (SiO₂) layer, a silicon nitride (SiNₓ) layer, a silicon oxide nitride (SiOₓN_{y}; x>y) layer, a silicon nitride oxide (SiNₓO_{y}; x>y) layer, an aluminum oxide layer, and a tantalum oxide layer, which may be used as appropriate. Here, as the gate insulating film, a silicon oxide (SiOₓ) layer (thickness: 80-250 nm, for example, 150 nm) is formed using CVD. As the upper gate conductive film, a conductive film similar to the gate electrode 3 of the TFT 101 may be used. Here, as the upper gate conductive film, a multilayer film including a Ti film as a lower layer and a Cu film as an upper layer is formed by sputtering.

Next, the upper gate conductive film and the gate insulating film are etched to obtain the gate electrode 32 and the gate insulating layer 30. Here, a resist mask is formed on the upper gate conductive film, and the upper gate conductive film and the gate insulating film are simultaneously etched (here, dry etching) using the resist mask. Therefore, a portion of the gate insulating film that is not covered by the gate electrode 32 is removed.

Thereafter, a plasma treatment may be performed on the entire surface of the substrate 1 from above the gate electrode 32. As a result, the resistance of only a portion of the semiconductor layer 27 that is not covered by the gate electrode 32 is reduced by the plasma treatment.

Next, the interlayer insulating layer 35 (thickness: 100-500 nm, for example) is formed so as to cover the semiconductor layer 27, the gate insulating layer 30, and the gate electrode 32. The interlayer insulating layer 35 may be formed of one or a stack of a silicon oxide film, a silicon nitride film, a silicon oxide nitride film, and a silicon nitride oxide film. Here, as the interlayer insulating layer 35, a SiNₓ (thickness: 100 nm) film and a SiO₂ film (thickness: 300 nm) are successively formed by CVD.

Note that after patterning of the gate electrode 32 and the gate insulating layer 30, an insulating film (e.g., a nitride film of SiNₓ) that reduces an oxide semiconductor may be formed so as to be in contact with a portion of the upper surface of the semiconductor layer 7 that is exposed from the gate electrode 32. As a result, the exposed portion of the semiconductor layer 27 is reduced to have a reduced resistance (self-alignment structure). In this case, the above plasma treatment may not be performed.

Thereafter, a contact hole through which a portion of the semiconductor layer 27 is exposed is formed in the interlayer insulating layer 35. Next, a conductive film for a source interconnect is formed on the interlayer insulating layer 35 and in the contact hole. Here, a conductive film for a source interconnect that is similar to that of the TFT 101 (a multilayer film including a Ti film as a lower layer and an Al film as an upper layer) is used. Next, the conductive film for a source interconnect is patterned to obtain the source electrode 28 and the drain electrode 29. Thus, the TFT 105 is produced.

### Variations

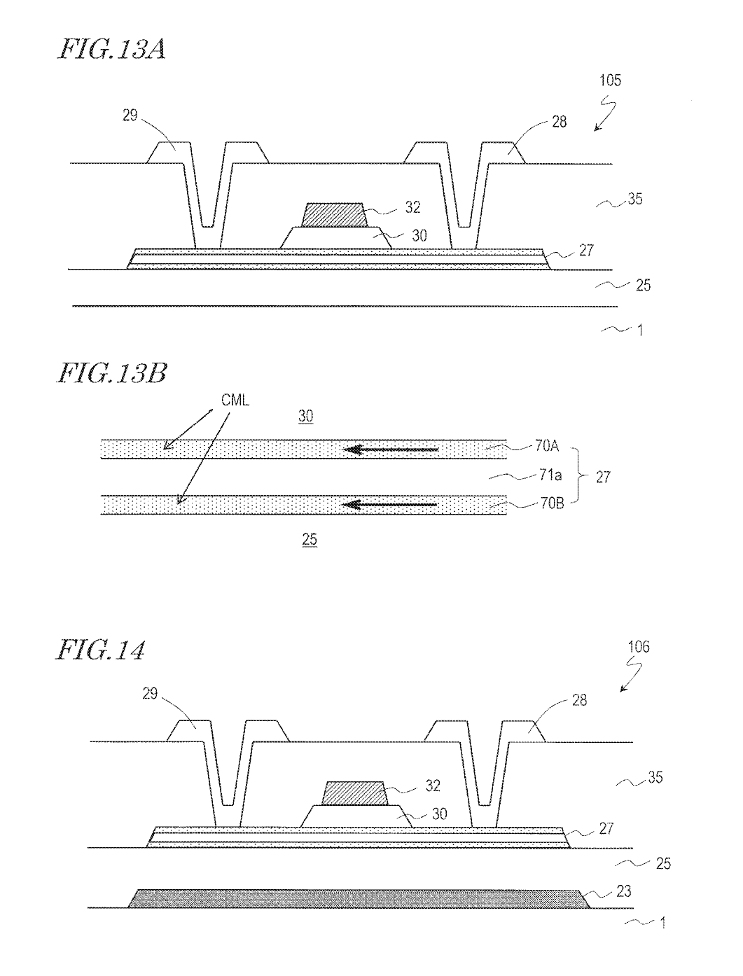

FIG. 14 is a cross-sectional view illustrating another TFT 106 according to this embodiment.

The TFT 106 is different from the TFT 105 of FIG. 13 in that the TFT 106 has a dual-gate structure in which a lower electrode 23 is provided between the substrate 1 and the lower insulating layer 25.

The lower electrode 23 is disposed so as to overlay at least the channel region 7c as viewed in the direction of the normal to the substrate 1. The lower electrode 23 may be a metal layer. As a result, the lower electrode 23 may function as a light blocking layer of the TFT 106. For example, the lower electrode 23 may be formed of the same conductive film of which the gate line GL (FIG. 1) is formed.

The lower electrode 23 may be grounded. As a result, characteristics of the TFT 106 can be reliably stabilized. The lower electrode 23 may be electronically connected to the source electrode 28. Alternatively, the lower electrode 23 may be electronically connected to the gate electrode 32 (or a gate bus line) so that the lower electrode 23 has the same potential as that of the gate electrode 32.

the ITT 106 has a dual-gate structure, and therefore, as with the TFT 103, not only the uppermost layer (closer to the gate insulating layer 30) but also the lowermost layer of the semiconductor layer 27 are preferably a channel formation layer 70. Thus, one of the channel formation layers 70 is preferably the lowermost layer of the semiconductor layer 27, and is preferably in contact with the lower insulating layer 25. As a result, the lower electrode 23 provides the effect of improving the on-current.

The TFT 106 is produced by a method similar to that for the TFT 105, except that the lower electrode 23 is formed on the substrate 1. The lower electrode 23 is formed by forming a conductive film for a lower electrode (thickness: 50-500 nm, for example) on the substrate 1, and patterning the conductive film. The conductive film for a lower electrode may be a film similar to that for the gate electrode 3 of the TFT 101. Here, as the conductive film for a lower electrode, a multilayer film including a Ti film a lower layer and a Cu film as an upper layer is formed by sputtering. The conductive film for a lower electrode is patterned by, for example, dry etching.

Next, the lower insulating layer 25 is formed so as to cover the lower electrode 23. The subsequent steps are similar to those of the TFT 105.

The TFTs 105 and 106 of this embodiment may also be applied as a pixel TFT and/or a circuit TFT in the active matrix substrate described above with reference to FIGS. 7-10.

### TFT Structure and Oxide Semiconductor

The TFT structure is not limited to those illustrated in the first to third embodiments. For example, while the TFT 101 of FIG. 1 has a top-contact structure in which the source and drain electrodes are in contact with the upper surface of the semiconductor layer, the TFT 101 may have bottom-contact structure in which the source and drain electrodes are in contact with the lower surface of the semiconductor layer. The configurations of the top- and bottom-gate structure TFTs are not limited to those described above.

In the above embodiments, the oxide semiconductor contained in the oxide semiconductor layer may be either an amorphous oxide semiconductor or a crystalline oxide semiconductor having a crystalline portion. Examples of the crystalline oxide semiconductor include a polycrystalline oxide semiconductor, a microcrystalline oxide semiconductor, and a crystalline oxide semiconductor whose c-axis is oriented substantially perpendicularly to the layer surface.

The oxide semiconductor layer may have a multilayer structure including an amorphous oxide semiconductor layer and a crystalline oxide semiconductor layer. Alternatively, the oxide semiconductor layer may include a plurality of crystalline oxide semiconductor layers having different crystal structures, or a plurality of amorphous oxide semiconductor layers. Materials, structures, and film formation methods for amorphous oxide semiconductors and the above crystalline oxide semiconductors, and the configuration of the oxide semiconductor layer having a multilayer structure, etc., are described in, for example, Japanese Laid-Open Patent Publication No. 2014-007399, the entire contents of which are herein incorporated by reference.

The oxide semiconductor layers (the channel formation layers 70 and the middle layers 71) included in the semiconductor layer 7 may each contain at least one metal element of In, Ga, and Zn, for example. The oxide semiconductor layer contains an In—Ga—Zn—O semiconductor (e.g., indium gallium zinc oxide), for example. Here, the In—Ga—Zn—O semiconductor is a ternary oxide of In (indium), Ga (gallium), and Zn (zinc). The proportions (composition ratio) of In, Ga, and Zn in the In—Ga—Zn—O semiconductor are not particularly limited. Examples of the composition ratio include In:Ga:Zn=2:2:1, In:Ga:Zn=1:1:1, and In:Ga:Zn:=1:1:2. Such an oxide semiconductor layer may be formed of an oxide semiconductor film containing the In—Ga—Zn—O semiconductor.

The In—Ga—Zn—O semiconductor may be either amorphous or crystalline. The crystalline In—Ga—Zn—O semiconductor is preferably one whose c-axis is oriented substantially perpendicularly to the layer surface.

Note that the crystal structure of the crystalline In—Ga—Zn—O semiconductor is described in, for example, Japanese Laid-Open Patent. Publication No. 2014-007399 above, Japanese Laid-Open Patent Publication No. 2012-134475, Japanese Laid-Open Patent Publication No. 2014-209727, etc. The entire contents of Japanese Laid-Open Patent Publication Nos. 2010-134475 and 2014-209727 are herein incorporated by reference. A TFT having the In—Ga—Zn—O semiconductor layer has a high mobility (more than 20 times as high as that of an a-SiTFT) and a low leakage current (less than one hundredth of that of an a-SiTFT), and therefore, is preferably used as a drive TFT (e.g., a TFT included in a drive circuit provided on the same substrate on which a display region including a plurality of pixels is provided, around the display region) and a pixel TFT (a TFT provided at a pixel).

The channel formation layers 70 and the middle layers 71 may contain other oxide semiconductors instead of the In—Ga—Zn—O semiconductor. For example, the channel formation layers 70 and the middle layers 71 may contain an In—Sn—Zn—O semiconductor (e.g., In₂O₃—SnO₂—ZnO; InSnZnO). The In—Sn—Zn—O semiconductor is a ternary oxide of In (indium), Sn (tin), and Zn (zinc). Alternatively, the oxide semiconductor layer may contain an In—Al—Zn—O semiconductor, an In—Al—Sn—Zn—O semiconductor, a Zn—O semiconductor, an In—Zn—O semiconductor, a Zn—Ti—O semiconductor, a Cd—Ge—O semiconductor, Cd—Pb—O semiconductor, a CdO (cadmium oxide), a Mg—Zn—O semiconductor, an In—Ga—Sn—O semiconductor, an In—Ga—O semiconductor, a Zr—In—Zn—O semiconductor, a Hf—In—Zn—O semiconductor, an Al—Ga—Zn—O semiconductor, a Ga—Zn—O semiconductor, an In—Ga—Zn—Sn—O semiconductor, etc.

The above embodiments are preferably applied to an active matrix substrate including an oxide semiconductor TFT. The active matrix substrate may be used in various display devices, such as a liquid crystal display device, an organic EL display device, and an inorganic EL display device, electronic apparatuses including a display device, etc. In the active matrix substrate, the oxide semiconductor TFT is used not only as a switching element provided at each pixel, but also as a circuit element for a peripheral circuit, such as a driver (monolithic formation). In such a case, the oxide semiconductor TFT of the present invention, which includes, as the active layer, an oxide semiconductor layer having a high mobility (e.g., 10 cm²/Vs or higher), can be preferably used as the circuit element.

The embodiments of the present invention may be widely applied to various semiconductor devices having an oxide semiconductor TFT. For example, the embodiments of the present invention are applicable to various electronic devices, such as circuit substrates (e.g., an active matrix substrate), display devices (e.g., a liquid crystal display device, an organic electroluminescent (EL) display device, an inorganic electroluminescent display device, and a MEMS display device), imaging devices (e.g., an imaging sensor), image input devices, finger reading devices, and semiconductor memories.

This application is based on Japanese Patent Applications No. 2017-188268 filed on Sep. 28, 2017, the entire contents of which are hereby incorporated by reference.

What is claimed is:

1. A semiconductor device comprising:
a substrate; and
a plurality of thin-film transistors supported by the substrate,
wherein
at least one of the plurality of thin-film transistors includes a semiconductor layer, a gate electrode, a gate insulating layer provided between the gate electrode and the semiconductor laver, and a source electrode and a drain electrode electronically connected to the semiconductor layer,
the semiconductor layer has a multilayer structure including
a plurality of channel formation layers including a first channel formation layer and a second channel formation layer, and
at least one middle layer including a first middle layer provided between the first channel formation layer and the second channel formation layer,
the first channel formation layer is disposed closer to the gate insulating layer than is the second channel formation layer, and is in contact with the gate insulating layer,
the plurality of channel formation layers and the at least one middle layer are all an oxide semiconductor layer, and the plurality of channel formation layers each have a mobility higher than that of the at least one middle layer.

2. The semiconductor device of claim 1, wherein
the plurality of channel formation layers and the at least one middle layer all include a first metal element and a second metal element, the first metal element is In, and the second metal element is one of Ga and Zn,
the atomic proportion of the first metal element to all metal elements contained in each of the plurality of channel formation layers is different from the atomic proportion of the first metal element to all metal elements contained in the at least one middle layer,
in each of the plurality of channel formation layers, the atomic proportion of the first metal element to all the metal elements is greater than or equal to the atomic proportion of the second metal element to all the metal elements, and
in the at least one middle layer, the atomic proportion of the first metal element to all the metal elements is smaller than or equal to the atomic proportion of the second metal element to all the metal elements.

3. A semiconductor device comprising:
a substrate; and
a plurality of thin-film transistors supported by the substrate,
wherein
at least one of the plurality of thin-film transistors includes a semiconductor layer, a gate electrode, a gate insulating layer provided between the gate electrode and the semiconductor layer, and a source electrode and a drain electrode electronically connected to the semiconductor layer,
the semiconductor layer has a multilayer structure including
a plurality of channel formation layers including a first channel formation layer and a second channel formation layer, and
at least one middle layer including a first middle layer provided between the first channel formation layer and the second channel formation layer,
the first channel formation layer is disposed closer to the gate insulating layer than is the second channel formation layer, and is in contact with the gate insulating layer,
the plurality of channel formation layers and the at least one middle layer are all an oxide semiconductor layer including a first metal element and a second metal element, the first metal element is In, and the second metal element is one of Ga and Zn,
the atomic proportion of the first metal element to all metal elements contained in in each of the plurality of channel formation layers is different from the atomic proportion of the first metal element to all metal elements contained in the at least one middle layer,
in each of the plurality of channel formation layers, the atomic proportion of the first metal element to all the metal elements is greater than or equal to the atomic proportion of the second metal element to all the metal elements, and
in the at least one middle layer, the atomic proportion of the first metal element to all the metal elements is smaller than or equal to the atomic proportion of the second metal element to all the metal elements.

4. The semiconductor device of claim 1, wherein
the first channel formation layer and the second channel formation layer have substantially the same composition.

5. The semiconductor device of claim 1, wherein
the first middle layer is in contact with the first channel formation layer and the second channel formation layer.

6. The semiconductor device of claim 1, wherein
the first channel formation layer and the second channel formation layer each have a thickness smaller than a thickness of the first middle layer.

7. The semiconductor device of claim 1, wherein
the plurality of channel formation layers further include a third channel formation layer provided on an opposite side of the second channel formation layer from the first middle layer, and
the at least one middle layer further includes a second middle layer provided between the third channel formation layer and the second channel formation layer.

8. The semiconductor device of claim 1, wherein
the gate electrode is disposed between the semiconductor layer and the substrate.

9. The semiconductor device of claim 8, wherein
the at least one thin-film transistor has a channel-etch structure, and
the multilayer structure of the semiconductor layer includes a protective layer as an uppermost layer, and the protective layer is an oxide semiconductor layer having a mobility lower than those of the plurality of channel formation layers.

10. The semiconductor device of claim 8, wherein
the at least one thin-film transistor has an etch-stop structure.

11. The semiconductor device of claim 8, wherein
the at least one thin-film transistor further includes an upper electrode provided on the semiconductor layer with an upper insulating layer interposed therebetween.

12. The semiconductor device of claim 11, wherein
one of the plurality of channel formation layers is an uppermost layer of the multilayer structure, and is in contact with the upper insulating layer.

13. The semiconductor device of claim 1, wherein
the gate electrode is disposed on an opposite side of the semiconductor layer from the substrate with the gate insulating layer interposed between the gate electrode and the semiconductor layer.

14. The semiconductor device of claim 13, wherein
the gate insulating layer is disposed on a portion of the semiconductor layer, and is located only between the semiconductor layer and the gate electrode,
the semiconductor device further includes an interlayer insulating layer covering the semiconductor layer, the gate electrode, and the gate insulating layer, and
the source electrode and the drain electrode are each disposed on the interlayer insulating layer, and are each in contact with the semiconductor layer in an opening provided in the interlayer insulating layer.

5. The semiconductor device of claim 13, wherein
the at least one thin-film transistor further includes
a lower electrode provided between the substrate and the semiconductor layer, and
a lower insulating layer provided between the lower electrode and the semiconductor layer.

16. The semiconductor device of claim 15, wherein
one of the plurality of channel formation layers is a lowermost layer of the multilayer structure, and is in contact with the lower insulating layer.

17. The semiconductor device of claim 1, wherein
the semiconductor device is an active matrix substrate having a display region including a plurality of pixels, and a non-display region other than the display region.

18. The semiconductor device of claim 17, wherein
the at least one thin-film transistor includes a pixel TFT provided at each of the plurality of pixels.

19. The semiconductor device of claim 17, further comprising:
a drive circuit provided in the non-display region, wherein
the at least one thin-film transistor includes a circuit TFT included in the drive circuit.

20. The semiconductor device of claim 1, wherein
the plurality of channel formation layers and the at least one middle layer all contain In, Ga, and Zn.
